(19) United States
(12) Patent Application Publication
(10) Pub. No.: US 2026/0032999 A1
(43) Pub. Date: Jan. 29, 2026

(54) SEMICONDUCTOR DEVICE

(71) Applicant: Samsung Electronics Co., Ltd., Suwon-si (KR)

(72) Inventors: Hyunggoo LEE, Suwon-si (KR); Gwanho KIM, Suwon-si (KR); Kyongbeom KOH, Suwon-si (KR); KI-IL KIM, Suwon-si (KR); Hyonwook Ra, Suwon-si (KR)

(21) Appl. No.: 19/181,761

(22) Filed: Apr. 17, 2025

(30) Foreign Application Priority Data
Jun. 18, 2024 (KR) 10-2024-0078981

(51) Int. Cl. H10D 84/90; H10D 89/10

(52) U.S. Cl. CPC H10D 84/964; H10D 84/953; H10D 84/981; H10D 89/10

(57) ABSTRACT

Provided is a semiconductor device including a substrate, a lower power line disposed on a lower portion of the substrate, a channel pattern, on the substrate, including a plurality of semiconductor patterns spaced apart from each other and stacked, a source/drain pattern connected to the channel pattern, a gate electrode between the substrate and each of the plurality of semiconductor patterns, and a rear surface filler structure penetrating the substrate to be disposed under the gate electrode. The rear surface filler structure includes a first filler pattern adjacent to the gate electrode, and a second filler pattern disposed under the first filler pattern. The first filler pattern covers an upper surface of the second filler pattern and a portion of each of side surfaces of the second filler pattern.

### CROSS-REFERENCE TO RELATED APPLICATIONS

This U.S. non-provisional patent application claims priority under 35 U.S.C. § 119 of Korean Patent Application No. 10-2024-0078981, filed on Jun. 18, 2024, the entire contents of which are hereby incorporated by reference.

### BACKGROUND

The present disclosure herein relates to a semiconductor device, and more particularly, to a semiconductor device including a field effect transistor.

A semiconductor device includes an integrated circuit composed of metal-oxide-semiconductor field effect transistors (MOSFET). As a size and a design rule of the semiconductor device are gradually decreasing, scaling down of the metal-oxide-semiconductor field effect transistors is also gradually being accelerated. As the metal-oxide-semiconductor field effect transistors are gradually scaled down, operation characteristics of the semiconductor device may be deteriorated. Accordingly, research on various methods for overcoming limitations caused by high-integration of the semiconductor device and forming the semiconductor device with improved performance is being conducted.

### SUMMARY

The present disclosure provides a semiconductor device with improved reliability and electrical characteristics.

A technical goal of the inventive concept is not limited to the goals mentioned above, and other technical goals that are not mentioned may be clearly understood from description below by those skilled in the art.

An embodiment of the inventive concept provides a semiconductor device including a substrate, a lower power line disposed on a lower portion of the substrate, a channel pattern on the substrate and including a plurality of semiconductor patterns spaced apart from each other and stacked, a source/drain pattern connected to the channel pattern, a gate electrode between the substrate and each of the plurality of semiconductor patterns, and a rear surface filler structure penetrating the substrate to be disposed under the gate electrode, wherein the rear surface filler structure includes a first filler pattern adjacent to the gate electrode, and a second filler pattern disposed under the first filler pattern, and wherein the first filler pattern covers an upper surface of the second filler pattern and a portion of each of side surfaces of the second filler pattern.

In an embodiment of the inventive concept, a semiconductor device includes a substrate including an active pattern, a lower power line buried in a lower portion of the substrate, a channel pattern on the active pattern and including a plurality of semiconductor patterns, the plurality of semiconductor patterns being spaced apart from each other and stacked, and including a lowermost first semiconductor pattern, a gate electrode crossing the active pattern, and including a first inner gate electrode interposed between the active pattern and the lowermost first semiconductor pattern, a source/drain pattern connected to the channel pattern, a rear surface active contact electrically connecting the lower power line and the source/drain pattern, and a rear surface filler structure disposed under the first inner gate electrode, wherein the rear surface filler structure includes a lower filler portion, and an upper filler portion on the lower filler portion, and wherein a slop of a sidewall of the upper filler portion is different from or the same as a slope of a sidewall of the lower filler portion.

In an embodiment of the inventive concept, a semiconductor device includes a substrate including an active pattern, an element isolation film provided on the substrate to define the active pattern, a channel pattern on the active pattern and including a plurality of semiconductor patterns, the plurality of semiconductor patterns being spaced apart from each other and stacked, and including a first semiconductor pattern, a second semiconductor pattern, and a third semiconductor pattern, source/drain patterns connected to the channel pattern, and including a first source/drain pattern and a second source/drain pattern horizontally spaced apart from each other, a gate electrode between the plurality of semiconductor patterns, and including a first inner electrode, a second inner electrode, and a third inner electrode interposed between adjacent semiconductor patterns among the plurality of semiconductor patterns, and an outer electrode on the third semiconductor pattern, a gate insulating film interposed between the gate electrode and the channel pattern, gate spacers on sidewalls of the gate electrode, a gate capping pattern on an upper surface of the gate electrode, an interlayer insulating layer covering the source/drain pattern and the gate capping pattern, an upper active contact penetrating the interlayer insulating layer to be electrically connected to the first source/drain pattern, a metal-semiconductor compound layer interposed between the upper active contact and the first source/drain pattern, a gate contact penetrating the interlayer insulating layer and the gate capping pattern to be electrically connected to the gate electrode, a first metal layer on the interlayer insulating layer and including a first line electrically connected to the gate contact, a second metal layer on the first metal layer and including a second line electrically connected to the first metal layer, a lower power line provided under the substrate, a rear surface active contact penetrating the substrate to electrically connect the lower power line and the second source/drain pattern, and a rear surface filler structure penetrating the substrate to be disposed under the gate insulating film on the first inner electrode, wherein the rear surface filler structure includes a first filler pattern adjacent to the gate insulating film, and a second filler pattern provided under the first filler pattern, wherein a bottom surface of the first filler pattern has a first level, wherein a bottom surface of the second filler pattern has a second level, and wherein the first level is higher than the second level.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIGS. 1 to 3 are conceptual views for describing logic cells of a semiconductor device according to example embodiments of the inventive concept;

FIG. 4 is a plan view for describing a semiconductor device according to example embodiments of the inventive concept;

FIGS. 5A to 5D are cross-sectional views respectively taken along line A-A′, line B-B′, line C-C′, and line D-D′ of FIG. 4;

FIGS. 6A to 6C are enlarged views illustrating example embodiments of region M of FIG. 5A;

FIG. 7 is a cross-sectional view for describing a semiconductor device according to another example embodiment of FIG. 5A; and

FIGS. 8A to 20D are diagrams illustrating a method for manufacturing a semiconductor device according to example embodiments of the inventive concept.

### DETAILED DESCRIPTION

Hereinafter, embodiments of the inventive concept will be described with reference to the accompanying drawings in more detail in order to more specifically describe the inventive concept. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

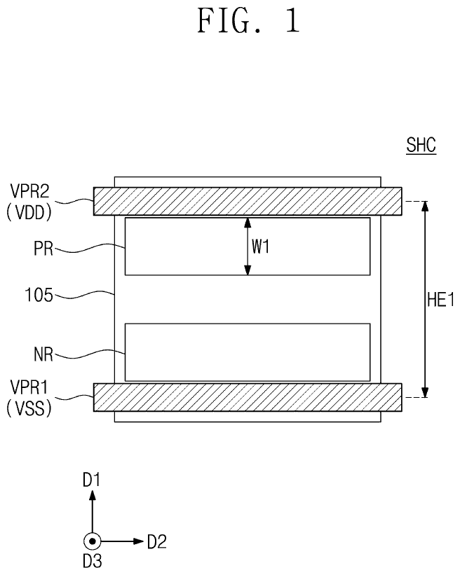

FIGS. 1 to 3 are conceptual views for describing logic cells of a semiconductor device according to example embodiments of the inventive concept.

Referring to FIG. 1, a single height cell SHC may be provided. Specifically, a first lower power line VPR1 and a second lower power line VPR2 may be provided on a lower portion of a substrate 100. Specifically, the first to third lower power lines VPR1 and VPR2 may be buried in an insulating substrate 105 provided under the substrate 100. The first lower power line VPR1 may be a path through which a source voltage VSS, for example, a ground voltage is provided. The second lower power line VPR2 may be a path through which a drain voltage VDD, for example, a power voltage is provided.

The single height cell SHC may be defined between the first lower power line VPR1 and the second lower power line VPR2. The single height cell SHC may include one PMOSFET region PR and one NMOSFET region NR. In other words, the single height cell SHC may have a structure of a CMOS provided between the first lower power line VPR1 and the second lower power line VPR2.

Each of the PMOSFET region PR and the NMOSFET region NR may have a first width W1 in a first direction D1. A length of the single height cell SHC in the first direction D1 may be defined as a first height HE1. The first height HE1 may be substantially the same as a distance (for example, a pitch) between the first lower power line VPR1 and the second lower power line VPR2.

The single height cell SHC may constitute one logic cell. In the present disclosure, the logic cell may mean a logic element (for example, AND, OR, XOR, XNOR, an inverter, or the like) that performs a specific function. For example, the logic cell may include transistors for constituting the logic element and lines connecting the transistors to each other.

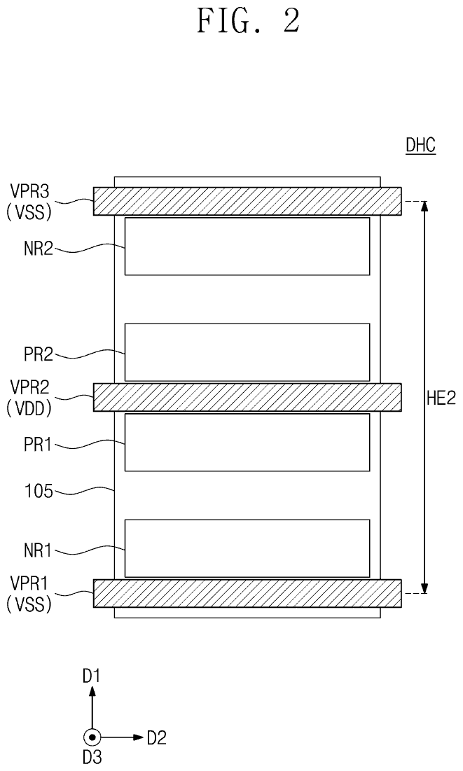

Referring to FIG. 2, a double height cell DHC may be provided. Specifically, a first lower power line VPR1, a second lower power line VPR2, and a third lower power line VPR3 may be provided on a lower portion of a substrate 100. Specifically, the first to third lower power lines VPR1 to VPR3 may be buried in an insulating substrate 105 provided under the substrate 100. The second lower power line VPR2 may be disposed between the first lower power line VPR1 and the third lower power line VPR3. The third lower power line VPR3 may be a path through which a source voltage VSS is provided.

The double height cell DHC may be defined between the first lower power line VPR1 and the third lower power line VPR3. The double height cell DHC may include a first PMOSFET region PR1, a second PMOSFET region PR2, a first NMOSFET region NR1, and a second NMOSFET region NR2.

The first NMOSFET region NR1 may be adjacent to the first lower power line VPR1. The second NMOSFET region NR2 may be adjacent to the third lower power line VPR3. The first and second PMOSFET regions PR1 and PR2 may be adjacent to the second lower power line VPR2. In a plan view, the second lower power line VPR2 may be disposed between the first and second PMOSFET regions PR1 and PR2.

A length of the double height cell DHC in the first direction D1 may be defined as a second height HE2. The second height HE2 may be substantially the same as a distance (for example, a pitch) between the first lower power line VPR1 and the third lower power line VPR3. The second height HE2 may be approximately twice the first height HE1 of FIG. 1. The first and second PMOSFET regions PR1 and PR2 of the double height cell DHC may operate together as one PMOSFET region. Accordingly, the PMOS transistor of the double height cell DHC may have a larger channel than the PMOS transistor of the single height cell SHC of FIG. 1.

For example, the PMOS transistor of the double height cell DHC may have a channel that is approximately twice as large as the channel of the PMOS transistor of the single height cell SHC. As a result, the double height cell DHC may operate at a higher speed than that of the single height cell SHC. In the inventive concept, the double height cell DHC illustrated in FIG. 2 may be defined as a multi-height cell. Although not shown, the multi-height cell may include a triple height cell of which a cell height is approximately three times the cell height of the single height cell SHC.

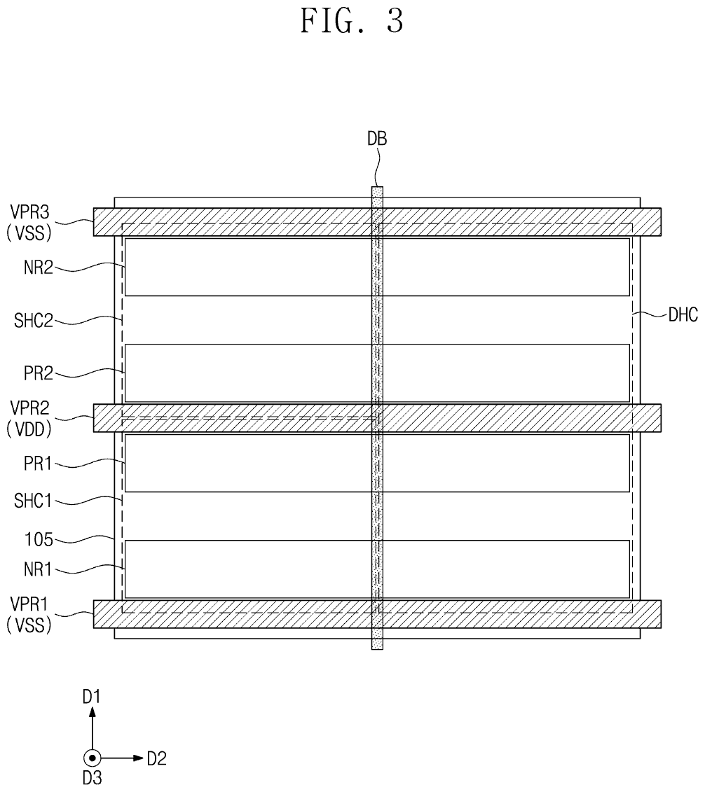

Referring to FIG. 3, a first single height cell SHC1, a second single height cell SHC2, and a double height cell DHC may be two-dimensionally disposed on the substrate 100. The first single height cell SHC1 may be disposed between the first and second lower power lines VPR1 and VPR2. The second single height cell SHC2 may be disposed between the second and third lower power lines VPR2 and VPR3. The second single height cell SHC2 may be adjacent to the first single height cell SHC1 in the first direction D1.

The double height cell DHC may be disposed between the first and third lower power lines VPR1 and VPR3. The double height cell DHC may be adjacent to the first and second single height cells SHC1 and SHC2 in a second direction D2.

An isolation structure DB may be provided between the first single height cell SHC1 and the double height cell DHC, and between the second single height cell SHC2 and the double height cell DHC. An active region of the double height cell DHC may be electrically isolated from an active region of each of the first and second single height cells SHC1 and SHC2 by the isolation structure DB.

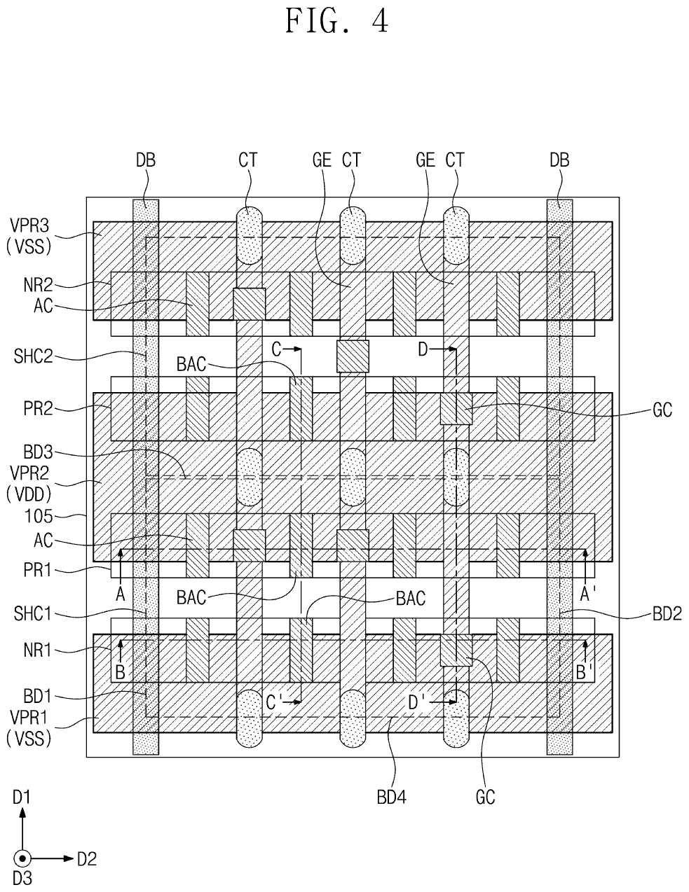

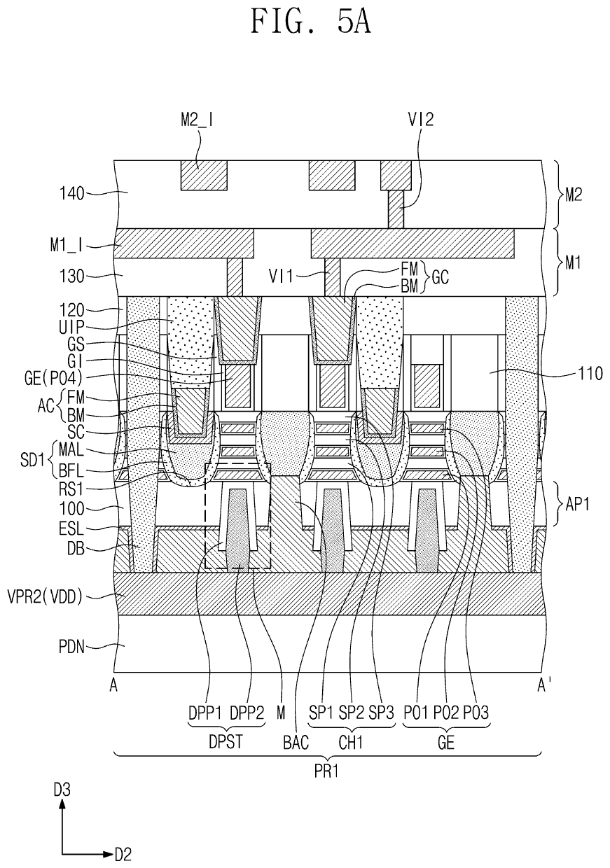

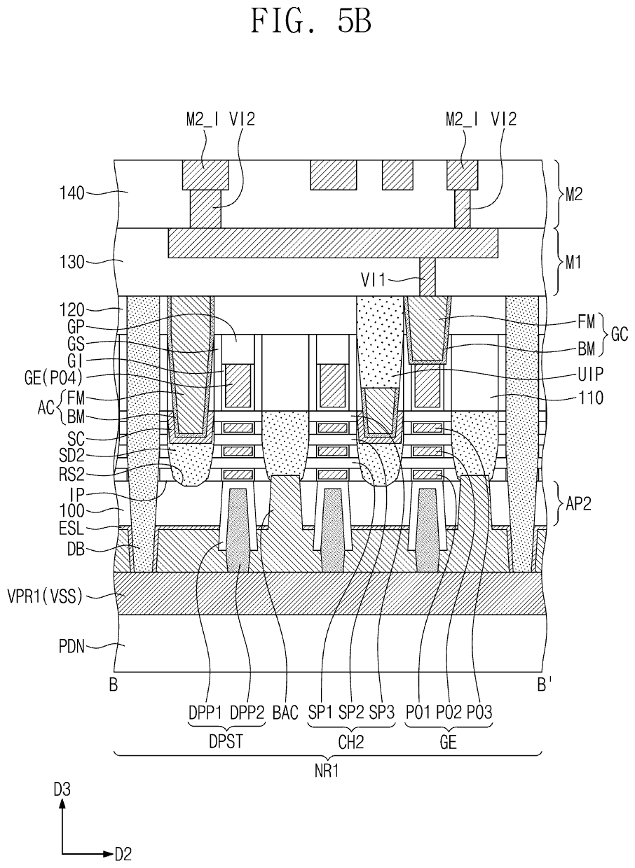

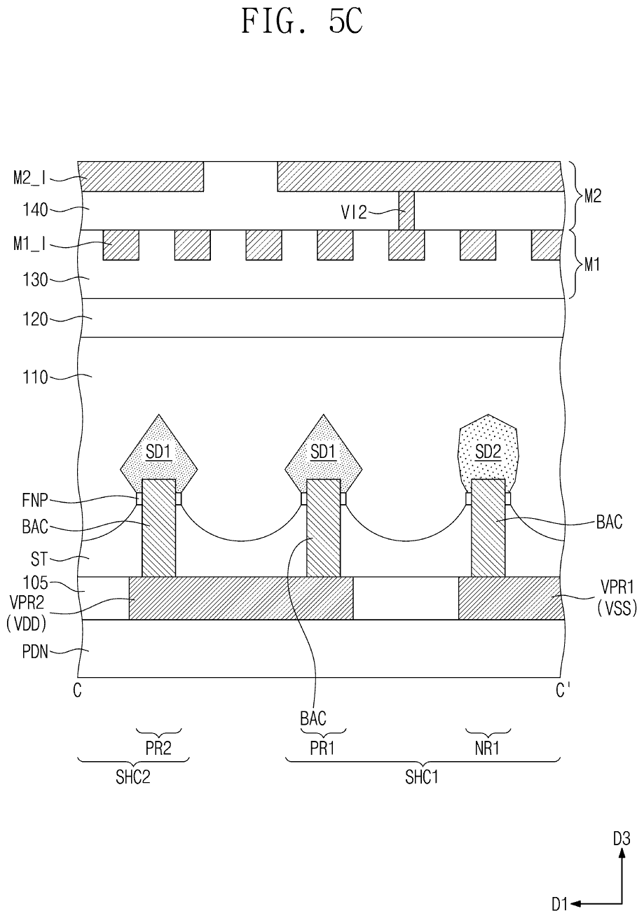

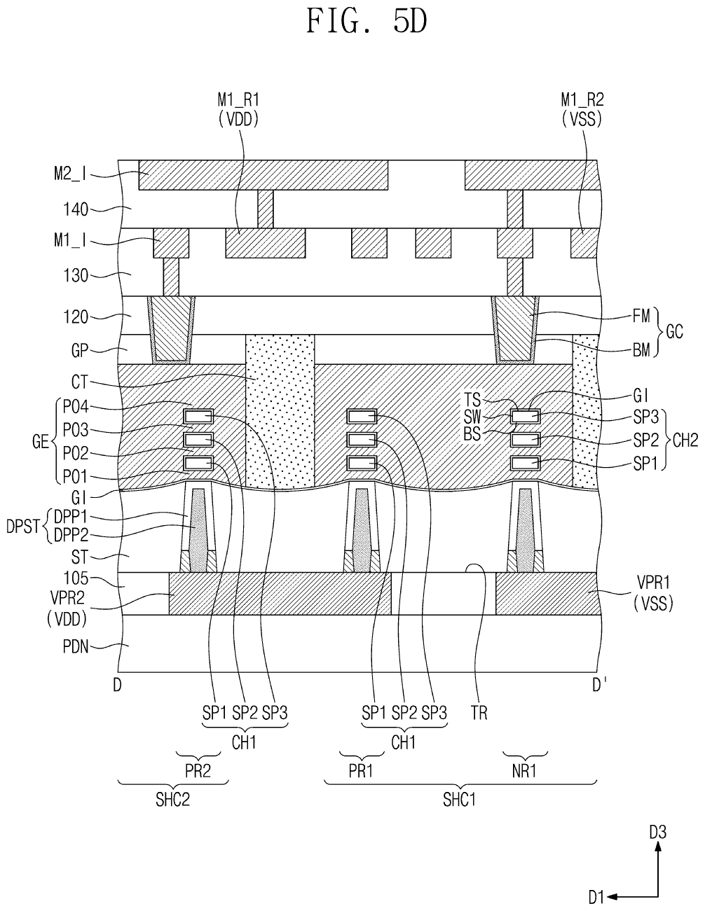

FIG. 4 is a plan view for describing a semiconductor device according to example embodiments of the inventive concept. FIG. 4 is a front side plan view seen from a front side of the semiconductor device. FIGS. 5A to 5D are cross-sectional views respectively taken along line A-A′, line B-B′, line C-C′, and line D-D′ of FIG. 4. The semiconductor devices illustrated in FIGS. 4 and 5A to 5E are examples more specifically showing the first and second single height cells SHC1 and SHC2 of FIG. 3.

Referring to FIGS. 4 and 5A to 5D, the first and second single height cells SHC1 and SHC2 may be provided on the substrate 100. Logic transistors that constitute a logic circuit may be disposed on each of the first and second single height cells SHC1 and SHC2. The substrate 100 may be a semiconductor substrate including silicon, germanium, silicon-germanium or the like, or a compound semiconductor substrate. For example, the substrate 100 may be a silicon substrate. As another example, the substrate 100 may include a silicon-based insulating layer, and may include a silicon oxide film, a silicon nitride film, or a silicon oxynitride film. Lower power lines VPR1 to VPR3 to be described later may be disposed under the substrate 100.

The substrate 100 may include a first PMOSFET region PR1, a second PMOSFET region PR2, a first NMOSFET region NR1, and a second NMOSFET region NR2. Each of the first PMOSFET region PR1, the second PMOSFET region PR2, the first NMOSFET region NR1, and the second NMOSFET region NR2 may extend lengthwise in the second direction D2. The first single height cell SHC1 may include the first NMOSFET region NR1 and the first PMOSFET region PR1, and the second single height cell SHC2 may include the second PMOSFET region PR2 and the second NMOSFET region NR2.

A first active pattern AP1 and a second active pattern AP2 may be defined by a trench TR formed on an upper portion of the substrate 100. The first active pattern AP1 may be provided on each of the first and second PMOSFET regions PR1 and PR2. The second active pattern AP2 may be provided on each of the first and second NMOSFET regions NR1 and NR2. The first and second active patterns AP1 and AP2 may extend lengthwise in the second direction D2. The first and second active patterns AP1 and AP2 may vertically protrude as portions of the substrate 100.

An element isolation film ST may fill the trench TR. The element isolation film ST may cover sidewalls of each of the first and second active patterns AP1 and AP2. The element isolation film ST may include a silicon oxide film. The element isolation film ST may not cover first and second channel patterns CH1 and CH2 to be described later.

A first channel pattern CH1 may be provided on the first active pattern AP1. A second channel pattern CH2 may be provided on the second active pattern AP2. Each of the first channel pattern CH1 and the second channel pattern CH2 may include a first semiconductor pattern SP1, a second semiconductor pattern SP2, and a third semiconductor pattern SP3 sequentially stacked. The first to third semiconductor patterns SP1, SP2, and SP3 may be spaced apart from each other in a vertical direction (that is, a third direction D3).

Each of the first to third semiconductor patterns SP1, SP2, and SP3 may include silicon (Si), germanium (Ge), or silicon-germanium (SiGe). For example, each of the first to third semiconductor patterns SP1, SP2, and SP3 may include crystalline silicon. Each of the first to third semiconductor patterns SP1, SP2, and SP3 may be a nanosheet.

A plurality of first source/drain patterns SD1 may be provided on the first active pattern AP1. A plurality of first recesses RS1 may be formed on an upper portion of the first active pattern AP1. The first source/drain patterns SD1 may be respectively provided in the first recesses RS1. The first source/drain patterns SD1 may be impurity regions having a first conductive type (for example, a P-type). The first channel pattern CH1 may be interposed between a pair of the first source/drain patterns SD1. In other words, stacked first to third semiconductor patterns SP1, SP2, and SP3 may connect the pair of the first source/drain patterns SD1 each other.

A plurality of second source/drain patterns SD2 may be provided on the second active pattern AP2. A plurality of second recesses RS2 may be formed on an upper portion of the second active pattern AP2. The second source/drain patterns SD2 may be respectively provided in the second recesses RS2. The second source/drain patterns SD2 may be impurity regions having a second conductive type (for example, an N-type). The second channel pattern CH2 may be interposed between a pair of the second source/drain patterns SD2. In other words, stacked first to third semiconductor patterns SP1, SP2, and SP3 may connect the pair of the second source/drain patterns SD2 each other.

The first and second source/drain patterns SD1 and SD2 may be epitaxial patterns formed in a selective epitaxial growth (SEG) process. For example, an upper surface of each of the first and second source/drain patterns SD1 and SD2 may be located at the substantially same level as an upper surface of the third semiconductor pattern SP3. As another example, the upper surface of each of the first and second source/drain patterns SD1 and SD2 may be located higher than the upper surface of the third semiconductor pattern SP3.

The first source/drain patterns SD1 may include a semiconductor element (for example, SiGe) having a greater lattice parameter than a semiconductor element of the first channel pattern CH1. Accordingly, the pair of the first source/drain patterns SD1 may provide a compressive stress to the first channel pattern CH1 therebetween. The second source/drain patterns SD2 may include the same semiconductor element (for example, Si) as the second channel pattern CH2.

The first source/drain patterns SD1 may each include a buffer layer BFL and a main layer MAL on the buffer layer BFL. Referring back to FIG. 5A, the buffer layer BFL may cover inner sidewalls of the first recess RS1. The main layer MAL may fill a remaining region of the first recess RS1 except for the buffer layer BFL. The main layer MAL may contact an inner surface of the buffer layer BFL. In example embodiments, an uppermost surface of the main layer MAL may be at the same level as an uppermost surface of the buffer layer BFL. A lowermost surface of the buffer layer BFL may be at a lower level in the third direction D3 than a lowermost surface of the main layer MAL. The main layer MAL may have a greater volume than the buffer layer BFL. The buffer layer BFL and the main layer MAL may each include silicon-germanium (SiGe). Specifically, the buffer layer BFL may contain germanium (Ge) having a relatively low concentration. According to another embodiment of the inventive concept, the buffer layer BFL may contain only silicon (Si) except for germanium (Ge). The buffer layer BFL may include germanium (Ge) having a concentration of 0 at % to about 30 at %.

The main layer MAL may contain germanium (Ge) having a relatively high concentration. For example, the main layer MAL may include germanium (Ge) having a concentration of about 30 at % to about 70 at %. A germanium (Ge) concentration of the main layer MAL may increase in the third direction D3. For example, the main layer MAL adjacent to the buffer layer BFL may have a germanium (Ge) concentration of about 40 at %, but an upper portion of the main layer MAL may have a germanium (Ge) concentration of about 60 at %.

The buffer layer BFL and the main layer MAL may each include an impurity causing the first source/drain pattern SD1 to become a P-type (for example, boron, gallium, or indium). The buffer layer BFL and the main layer MAL may each have an impurity concentration of about 1E18 atom/cm³ to about 5E22 atom/cm³. The main layer MAL may have a greater impurity concentration than the buffer layer BFL.

The buffer layer BFL may protect the main layer MAL during a process of replacing second semiconductor layers SAL to be described later with first to third inner electrodes PO1, PO2, and PO3 of a gate electrode GE. In other words, the buffer layer BFL may prevent an etching material removing the second semiconductor layers SAL from infiltrating into and etching the main layer MAL.

The second source/drain patterns SD2 may each include silicon (Si). The second source/drain pattern SD2 may further include an impurity (for example, phosphorous, arsenic, or antimony) causing the second source/drain pattern SD2 to become an N-type. The second source/drain pattern SD2 may have an impurity concentration of about 1E18 atom/cm³ to about 5E22 atom/cm³.

The gate electrodes GE crossing the first and second channel patterns CH1 and CH2 and extending lengthwise in the first direction D1 may be provided. The gate electrodes GE may be arranged with a first pitch in the second direction D2. The gate electrodes GE may vertically overlap the first and second channel patterns CH1 and CH2.

The gate electrode GE may include a first inner electrode PO1 interposed between the active pattern AP1 or AP2 and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring back to FIG. 5D, the gate electrode GE may be provided on an upper surface TS, a bottom surface BS, and both sidewalls SW of each of the first to third semiconductor patterns SP1, SP2, and SP3. In other words, the transistor according to the inventive concept may be a three-dimensional field effect transistor (for example, MBCFET or GAAFET) in which the gate electrode GE three-dimensionally surrounds the channel thereof.

Representatively, the first single height cell SHC1 may have a first boundary BD1 and a second boundary BD2 opposed to each other in the second direction D2. The first and second boundaries BD1 and BD2 may extend lengthwise in the first direction D1. The first single height cell SHC1 may have a third boundary BD3 and a fourth boundary BD4 opposed to each other in the first direction D1. The third and fourth boundaries BD3 and BD4 may extend lengthwise in the second direction D2.

Gate cutting patterns CT may be disposed on a boundary of each of the first and second single height cells SHC1 and SHC2 in the second direction D2. For example, the gate cutting patterns CT may be disposed on the third and fourth boundaries BD3 and BD4 of the first single height cell SHC1. The gate cutting patterns CT may be arranged with the first pitch along the third boundary BD3. The gate cutting patterns CT may be arranged with the first pitch along the fourth boundary BD4. In a plan view, the gate cutting patterns CT on the third and fourth boundaries BD3 and BD4 may be disposed so as to respectively overlap the gate electrodes GE. The gate cutting patterns CT may include an insulating material such as a silicon oxide film, a silicon nitride film, or a combination thereof.

The gate electrode GE on the first single height cell SHC1 and the gate electrode GE on the second single height cell SHC2 may be separated by the gate cutting pattern CT. The gate cutting pattern CT may be interposed between the gate electrode GE on the first single height cell SHC1 and the gate electrode GE on the second single height cell SHC2 aligned therewith in the first direction D1. In other words, the gate electrode GE extending in the first direction D1 may be divided into a plurality of gate electrodes GE by the gate cutting pattern CT.

Referring back to FIGS. 4 and 5A to 5D, a pair of gate spacers GS may be respectively disposed on both sidewalls of the outer electrode PO4 of the gate electrode GE. The gate spacers GS may extend along the gate electrode GE in the first direction D1. Upper surfaces of the gate spacers GS may be higher than an upper surface of the gate electrode GE. The upper surfaces of the gate spacers GS may be coplanar with an upper surface of a first interlayer insulating layer 110 to be described later. The gate spacers GS may include at least one of SiCN, SiCON, or SiN. As another example, the gate spacers GS may include a multi-layered film composed of at least two of SiCN, SiCON, or SiN.

A gate capping pattern GP may be provided on the gate electrode GE. The gate capping pattern GP may extend along the gate electrode GE in the first direction D1. The gate capping pattern GP may include a material having etching selectivity with respect to first and second interlayer insulating layers 110 and 120 to be described later. Specifically, the gate capping pattern GP may include at least one of SiON, SiCN, SiCON, or SiN.

A gate insulating film GI may be interposed between the gate electrode GE and the first channel pattern CH1, and between the gate electrode GE and the second channel pattern CH2. The gate insulating film GI may cover the upper surface TS, the bottom surface BS, and the both sidewalls SW of each of the first to third semiconductor patterns SP1, SP2, and SP3. The gate insulating film GI may cover an upper surface of the element isolation film ST under the gate electrode GE. The gate insulating film GI may cover an upper surface of a rear surface filler structure DPST under the gate electrode GE (see FIG. 5D). The gate insulating film GI may be interposed between the first inner electrode PO1 and the rear surface filler structure DPST.

According to an embodiment of the inventive concept, the gate insulating film GI may include a silicon oxide film, a silicon oxynitride film, and/or a high dielectric film. The high dielectric film may include a high dielectric material having a higher dielectric constant than a silicon oxide film. For example, the high dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The gate electrode GE may include a first metal pattern, and a second metal pattern on the first metal pattern. The first metal pattern may be provided on the gate insulating film GI to be adjacent to the first to third semiconductor patterns SP1, SP2, and SP3. The first metal pattern may include a work function metal that controls a threshold voltage of the transistor. A targeted threshold voltage of the transistor may be achieved by controlling a thickness and a composition of the first metal pattern. For example, the first to third inner electrodes PO1, PO2, and PO3 of the gate electrode GE may be composed of the first metal pattern which is a work function metal.

The first metal pattern may include a metal nitride film. For example, the first metal pattern may include nitrogen (N) and at least one metal selected from the group consisting of titanium (Ti), tantalum (Ta), aluminum (Al), tungsten (W), molybdenum (Mo) and a combination thereof. Moreover, the first metal pattern may further include carbon (C). The first metal pattern may include a plurality of stacked work function metal films.

The second metal pattern may include metal having lower resistance than that of the first metal pattern. For example, the second metal pattern may include at least one metal selected from the group consisting of tungsten (W), aluminum (Al), titanium (Ti), tantalum (Ta), and a combination thereof. For example, the outer electrode PO4 of the gate electrode GE may include the first metal pattern, and the second metal pattern on the first metal pattern.

Referring back to FIGS. 4 and 5B, inner spacers IP may be provided on the first and second NMOSFET regions NR1 and NR2. In other words, the inner spacers IP may be provided on the second active pattern AP2. The inner spacers IP may be respectively interposed between the first to third inner electrodes PO1, PO2, and PO3 of the gate electrode GE and the second source/drain pattern SD2. The inner spacers IP may be in direct contact with the second source/drain pattern SD2. Each of the first to third inner electrodes PO1, PO2, and PO3 of the gate electrode GE may be spaced apart from the second source/drain pattern SD2 by the inner spacers IP.

The first interlayer insulating layer 110 may be provided on the substrate 100. The first interlayer insulating layer 110 may cover sidewalls of the gate spacers GS and the first and second source/drain patterns SD1 and SD2. An upper surface of the first interlayer insulating layer 110 may be substantially coplanar with an upper surface of the gate capping pattern GP and an upper surface of the gate spacer GS. A second interlayer insulating layer 120 covering the gate capping pattern GP may be disposed on the first interlayer insulating layer 110. The second interlayer insulating layer 120 may contact upper surfaces of the gate capping pattern GP and the first interlayer insulating layer 110. A third interlayer insulating layer 130 may be provided on the second interlayer insulating layer 120. The third interlayer insulating layer 130 may contact an upper surface of the second interlayer insulating layer 120. A fourth interlayer insulating layer 140 may be provided on the third interlayer insulating layer 130. The fourth interlayer insulating layer 140 may contact an upper surface of the third interlayer insulating layer 130. For example, the first to fourth interlayer insulating layers 110 to 140 may include a silicon oxide film.

A pair of isolation structures DB opposed to each other in the second direction D2 may be provided on both sides of each of the first and second single height cells SHC1 and SHC2. For example, the pair of isolation structures DB may be respectively provided on the first and second boundaries BD1 and BD2 of the first single height cell SHC1. The isolation structure DB may extend lengthwise parallel to the gate electrodes GE in the first direction D1. A pitch between the isolation structure DB and the gate electrode GE adjacent thereto may be the same as the first pitch (i.e., the first pitch in the second direction D2 between adjacent gate electrodes GE).

The isolation structure DB may penetrate the gate capping pattern GP and the gate electrode GE to extend to the insides of the first and second active patterns AP1 and AP2. The isolation structure DB may penetrate an upper portion of each of the first and second active patterns AP1 and AP2. For example, a lower surface of the isolation structure DB may be at a lower level in the third direction D3 than upper surfaces of the first and second active patterns AP1 and AP2. The isolation structure DB may electrically isolate an active region of each of the first and second single height cells SHC1 and SHC2 from an active region of another adjacent cell.

Upper active contacts AC penetrating the first and second interlayer insulating layers 110 and 120 to be respectively electrically connected to the first and second source/drain patterns SD1 and SD2 may be provided. Each of the upper active contacts AC may be provided so as to be adjacent to one side of the gate electrode GE. In a plan view, the upper active contact AC may have a form of a bar extending in the first direction D1.

The upper active contact AC may be a self-aligned contact. In other words, the upper active contact AC may be formed self-aligned using the gate capping pattern GP and the gate spacer GS. For example, the upper active contact AC may at least partially cover a sidewall of the gate spacer GS. Although not shown, the upper active contact AC may partially cover an upper surface of the gate capping pattern GP.

A metal-semiconductor compound layer SC, for example, a silicide layer may be interposed between the upper active contact AC and the first source/drain pattern SD1, and between the upper active contact AC and the second source/drain pattern SD2. The upper active contact AC may be electrically connected to the source/drain patterns SD1 to SD2 through the metal-semiconductor compound layer SC. For example, the metal-semiconductor compound layer SC may include at least one of titanium silicide, tantalum silicide, tungsten silicide, nickel silicide or cobalt silicide.

Gate contacts GC penetrating the second interlayer insulating layer 120 and the gate capping pattern GP to be respectively electrically connected to the gate electrodes GE may be provided. Upper surfaces of the gate contacts GC may be coplanar with an upper surface of the second interlayer insulating layer 120. In a plan view, two gate contacts GC on the first single height cell SHC1 may be disposed so as to overlap the first PMOSFET region PR1. In other words, the two gate contacts GC on the first single height cell SHC1 may be provided on the first active pattern AP1 (see FIG. 5A). In a plan view, one gate contact GC on the first single height cell SHC1 may be disposed so as to overlap the first NMOSFET region NR1. In other words, one gate contact GC on the first single height cell SHC1 may be provided on the second active pattern AP2 (see FIG. 5B).

The gate contact GC may be freely disposed on the gate electrode GE without limitation of a position. For example, the gate contacts GC on the second single height cell SHC2 may be respectively disposed on the second PMOSFET region PR2, the second NMOSFET region NR2 and the element isolation film ST that fills the trench TR (see FIG. 4).

According to an embodiment of the inventive concept, referring to FIGS. 5A and 5B, the gate contact GC may be in direct contact with an upper surface of the outer electrode PO4. An upper portion of the upper active contact AC adjacent to the gate contact GC may be filled with an upper insulating pattern UIP. A bottom surface of the upper insulating pattern UIP may be lower than a bottom surface of the gate contact GC. In other words, an upper surface of the upper active contact AC adjacent to the gate contact GC may be lower than the bottom surface of the gate contact GC due to the upper insulating pattern UIP. Accordingly, a phenomenon that the gate contact GC is in contact with the upper active contact AC adjacent thereto to generate a short circuit may be prevented. For example, the upper insulating pattern UIP may include a silicon-based insulating material (for example, a silicon oxide film, a silicon nitride film, or a silicon oxynitride film).

Each of the upper active contact AC and the gate contact GC may include a conductive pattern FM, and a barrier pattern BM surrounding the conductive pattern FM. The barrier pattern BM may contact bottom and side surfaces of the conductive pattern FM. For example, the conductive pattern FM may include at least one metal of aluminum, copper, tungsten, molybdenum, or cobalt. The barrier pattern BM may cover sidewalls and a bottom surface of the conductive pattern FM. The barrier pattern BM may include a metal film/metal nitride film. The metal film may include at least one of titanium, tantalum, tungsten, nickel, cobalt, or platinum. The metal nitride film may include at least one of a titanium nitride (TiN) film, a tantalum nitride (TaN) film, a tungsten nitride (WN) film, a nickel nitride (NiN) film, a cobalt nitride (CoN) film, or a platinum nitride (PtN) film.

Referring back to FIGS. 4, and 5A to 5D, first to third lower power lines VPR1 to VPR3 may be provided on a lower portion of the substrate 100. Specifically, the first to third lower power lines VPR1 to VPR3 may be buried in an insulating substrate 105 provided under the substrate 100. The first to third lower power lines VPR1 to VPR3 may extend lengthwise parallel to each other in the second direction D2. The first lower power line VPR1 may be disposed on the fourth boundary BD4 of the first single height cell SHC1. The second lower power line VPR2 may be disposed on the third boundary BD3 of the first lower power line SHC1. In other words, the first single height cell SHC1 may be defined between the first lower power line VPR1 and the second lower power line VPR2. The second single height cell SHC2 may be defined between the second lower power line VPR2 and the third lower power line VPR3.

According to an embodiment of the inventive concept, the first lower power line VPR1 may vertically overlap the first NMOSFET region NR1. The second lower power line VPR2 may vertically overlap the first PMOSFET region PR1 and the second PMOSFET region PR2. The third lower power line VPR3 may vertically overlap the second NMOSFET region NR2.

The first to third lower power lines VPR1 to VPR3 may include at least one selected from the group consisting of copper, molybdenum, tungsten, ruthenium, and a combination thereof.

A power transfer network layer PDN may be provided on a bottom surface of the insulating substrate 105. The power transfer network layer PDN may include a plurality of lower lines electrically connected to the first to third lower power lines VPR1 to VPR3. For example, the power transfer network layer PDN may include a line network for applying a source voltage VSS to the first to third lower power lines VPR1 to VPR3. The power transfer network layer PDN may include the line network for applying a drain voltage VDD to the second lower power line VPR2.

Referring back to FIGS. 4, 5A, 5B, and 5C, a rear surface active contact BAC penetrating the substrate 100 to vertically extend from the second lower power line VPR2 to the first source/drain pattern SD1 may be provided. The rear surface active contact BAC penetrating the substrate 100 to vertically extend from the first lower power line VPR1 to the second source/drain pattern SD2 may be provided.

Specifically, the rear surface active contacts BAC disposed under the substrate 100 may have a shape in which a lower width thereof is wide. For example, a width of a lower portion of each of the rear surface active contacts BAC may be wider than a width of an upper portion of the rear surface active contacts BAC. Each of the rear surface active contacts BAC may have a shape of a bar or plate extending in the second direction D2 between a pair of isolation structures DB in a plan view. In a plan view, the rear surface active contacts BAC may have a shape of a bar or plate separated by the rear surface filler structure DPST to be described later.

The rear surface active contact BAC may vertically extend to the first source/drain pattern SD1 or the second source/drain pattern SD2 not in contact with the upper active contact AC. Uppermost surfaces of the rear surface active contacts BAC may be at a higher level in the third direction D3 than an upper surface of the substrate 100 and an upper surface of the element isolation film ST. For example, uppermost surfaces of the rear surface active contacts BAC may be at a higher level in the third direction D3 than lowermost surfaces of the first source/drain pattern SD1 and the second source/drain pattern SD2. Fence patterns FNP may be formed on side surfaces of the rear surface active contact BAC, contacting the side surfaces of the rear surface active contact BAC and lower surfaces of the first source/drain pattern SD1 or the second source/drain pattern SD2. Specifically, the rear surface active contact BAC may include a body and a protrusion on the body. The body may be buried in the insulating substrate 105 to be electrically connected to the lower power lines VPR1 to VPR3 to be described later. The protrusion may penetrate the substrate 100 to be electrically connected to the first and second source/drain patterns SD1 and SD2.

An etch stopping layer ESL may be provided between the bodies of the rear surface active contacts BAC and the substrate 100. The etch stopping layer ESL may include a different material from the substrate 100.

The rear surface active contact BAC may have a form of a conductive column vertically and electrically connecting the second lower power line VPR2 and the first source/drain pattern SD1, or the first lower power line VPR1 and the second source/drain pattern SD2. The drain voltage VDD may be applied to the first source/drain pattern SD1 through the rear surface active contact BAC, and the source voltage VSS may be applied to the second source/drain pattern SD2 through the rear surface active contact BAC.

Although not shown, a metal-semiconductor compound layer may be provided between each of the rear surface active contacts BAC and the source/drain pattern SD1 or SD2. For example, the metal-semiconductor compound layer may be a silicide layer. The rear surface active contacts BAC may be electrically connected to the first source/drain pattern SD1 or the second source/drain pattern SD2 through the metal-semiconductor compound layer. For example, the metal-semiconductor compound layer may include at least one of titanium silicide, tantalum silicide, tungsten silicide, nickel silicide or cobalt silicide.

The rear surface active contacts BAC may include a rear surface conductive pattern and a rear surface barrier pattern surrounding the rear surface conductive pattern. The rear surface barrier pattern may cover sidewalls and an upper surface of the rear surface conductive pattern. For example, the rear surface conductive pattern may include at least one metal of aluminum, copper, tungsten, molybdenum, or cobalt. The rear surface barrier pattern may cover sidewalls and an upper surface of a lower conductive pattern. The rear surface barrier pattern may include a metal film/metal nitride film. The metal film may include at least one of titanium, tantalum, tungsten, nickel, cobalt, or platinum. The metal nitride film may include at least one of a titanium nitride (TiN) film, a tantalum nitride (TaN) film, a tungsten nitride (WN) film, a nickel nitride (NiN) film, a cobalt nitride (CoN) film, or a platinum nitride (PtN) film. The rear surface conductive pattern may include the same material as the conductive pattern FM described above, and the rear surface barrier pattern may include the same material as the barrier pattern BM described above.

The rear surface filler structure DPST penetrating the substrate 100, the body of the rear surface active contact BAC and the etch stopping layer ESL may be provided under the gate electrode GE. The rear surface filler structure DPST may extend from an upper surface of the lower power line VPR1 or VPR2 to a bottom surface of the gate insulating film GI surrounding the first inner electrode PO1. For example, the rear surface filler structure DPST may be in direct contact with the bottom surface of the gate insulating film GI.

An uppermost surface of the rear surface filler structure DPST may be located at a lower level in the third direction D3 than an uppermost surface of the rear surface active contact BAC. For example, the uppermost surface of the rear surface active contact BAC may be located at a higher level in the third direction D3 than the uppermost surface of the rear surface filler structure DPST. A bottom surface of the rear surface filler structure DPST may be substantially coplanar with a bottom surface of the rear surface active contact BAC. For example, a lowermost surface of the rear surface active contact BAC may be located at the same level as a lowermost surface of the rear surface filler structure DPST.

Specifically, the rear surface filler structure DPST may include a first filler pattern DPP1 adjacent to the first inner electrode PO1 of the gate electrode GE and a second filler pattern DPP2 disposed under the first filler pattern DPP1. The first filler pattern DPP1 may cover an upper surface of the second filler pattern DPP2 and a portion of each of side surfaces of the second filler pattern DPP2. In other words, the first filler pattern DPP1 may extend from one side surface of the second filler pattern DPP2 via the upper surface thereof to the other side surface thereof.

A lowermost surface of the rear surface active contact BAC may be located at a lower level in the third direction D3 than a lowermost surface of the first filler pattern DPP1 of the rear surface filler structure DPST, and the lowermost surface of the rear surface active contact BAC may be located at the substantially same level in the third direction D3 as a lowermost surface of the second filler pattern DPP2 of the rear surface filler structure DPST. For example, the lowermost surface of the first filler pattern DPP1 may be located at a higher level in the third direction D3 than the lowermost surface of the second filler pattern DPP2.

In other words, the lowermost surface or bottom surface of the first filler pattern DPP1 may have a first level in the third direction D3, and the lowermost surface or bottom surface of the second filler pattern DPP2 may have a second level in the third direction D3. The lowermost surface or bottom surface of the rear surface active contact BAC may have a third level in the third direction D3. The first level may be higher than the second level. The second level may be the same as the third level.

The rear surface filler structure DPST may include the first filler pattern DPP1 and the second filler pattern DPP2 to have a double layer structure. Each of side surfaces of the rear surface filler structure DPST may have a cascaded structure. The first filler pattern DPP1 may contact upper and side surfaces of the second filler pattern DPP2.

The first filler pattern DPP1 and the second filler pattern DPP2 may include different insulating materials. The insulating materials may include SiO₂, SiN, SiOC, TiO₂, or a combination thereof. Specifically, the first filler pattern DPP1 may include at least one of SiO₂, SiN, SiOC, or TiO₂, and the second filler pattern DPP2 may include another one, among SiO₂, SiN, SiOC, and TiO₂, different from the first filler pattern DPP1. As another example, the first and second filler patterns DPP1 and DPP2 may include the same insulating material as each other.

The rear surface filler structure DPST may separate the rear surface active contact BAC electrically connected to the source/drain pattern SD1 or SD2 by unit within the transistor. For example, the rear surface filler structure DPST may electrically separate the rear surface active contact BAC by the unit so as to individually select the source/drain pattern SD1 or SD2 to which the drain voltage VDD or the source voltage VSS is applied. Hereinafter, detailed description of the rear surface filler structure DPST will be made later.

Referring back to FIGS. 4, and 5A to 5D, a first metal layer M1 may be provided in the third interlayer insulating layer 130. The first metal layer M1 may include first lines M1_I. The first lines M1_I of the first metal layer M1 may extend parallel to each other in the second direction D2.

According to embodiments of the inventive concept, a power line for supplying power to the single height cell SHC may be provided under the substrate 100 in a form of the lower power lines VPR1 to VPR3. As another example, the lower power lines VPR1 to VPR3 may be buried in the substrate 100. Accordingly, the power line may be omitted in the first metal layer M1. The first lines M1_I for transferring a signal may be disposed in the first metal layer M1.

The first metal layer M1 may further include first vias VI1. The first vias VI1 may be respectively provided under the first lines M1_I of the first metal layer M1. The upper active contact AC and the first line M1_I of the first metal layer M1 may be electrically connected to each other through the first via VI1. The gate contact GC and the first line M1_I of the first metal layer M1 may be electrically connected to each other through the first via VI1.

The first line M1_I of the first metal layer M1 and the first via VI1 thereunder may be respectively formed in separate processes. In other words, each of the first line M1_I of the first metal layer M1 and the first via VI1 may be formed in a single damascene process. A semiconductor device according to the present embodiment may be formed using a process of manufacturing a semiconductor device having a design rule less than about 20 nm.

A second metal layer M2 may be provided in the fourth interlayer insulating layer 140. The second metal layer M2 may include a plurality of second lines M2_I. The second lines M2_I of the second metal layer M2 may each have a form of a line or bar extending in the first direction D1. In other words, the second lines M2_I may extend parallel to each other in the first direction D1.

The second metal layer M2 may further include second vias VI2 respectively provided under the second lines M2_I. The first line M1_I of the first metal layer M1 and the second line M2_I of the second metal layer M2 may be electrically connected to each other through the second via VI2. For example, the second line M2_I of the second metal layer M2 and the second via VI2 thereunder may be formed together in a dual damascene process.

The first line M1_I of the first metal layer M1 and the second line M2_I of the second metal layer M2 may include the same conductive material as each other or different conductive materials from each other. For example, the first line M1_I of the first metal layer M1 and the second line M2_I of the second metal layer M2 may include at least one metal material selected from aluminum, copper, tungsten, molybdenum, ruthenium, or cobalt. Although not shown, metal layers (for example, M3, M4, M5 . . . ) stacked on the fourth interlayer insulating layer 140 may be additionally disposed. Each of the stacked metal layers may include lines for routing between cells.

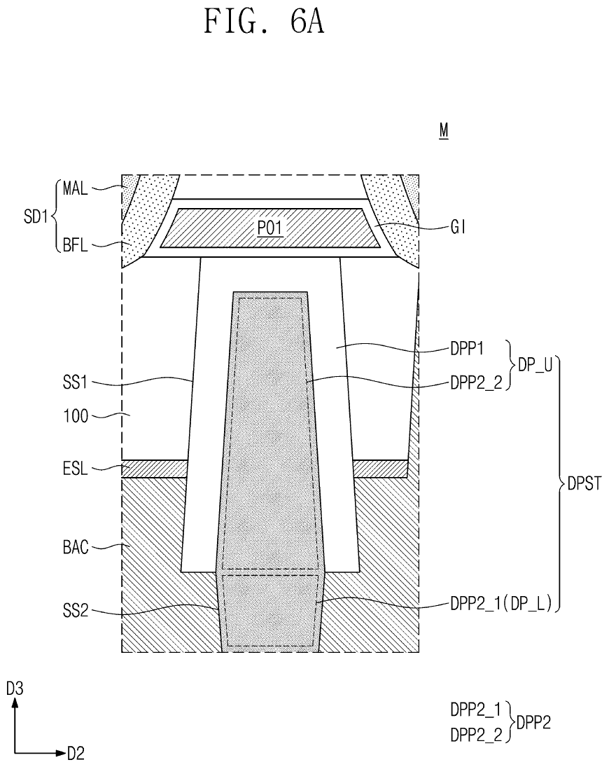

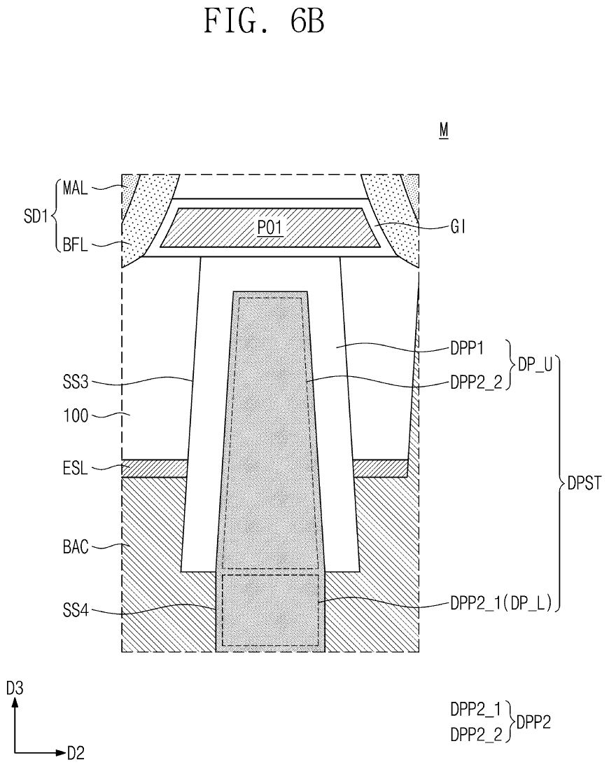

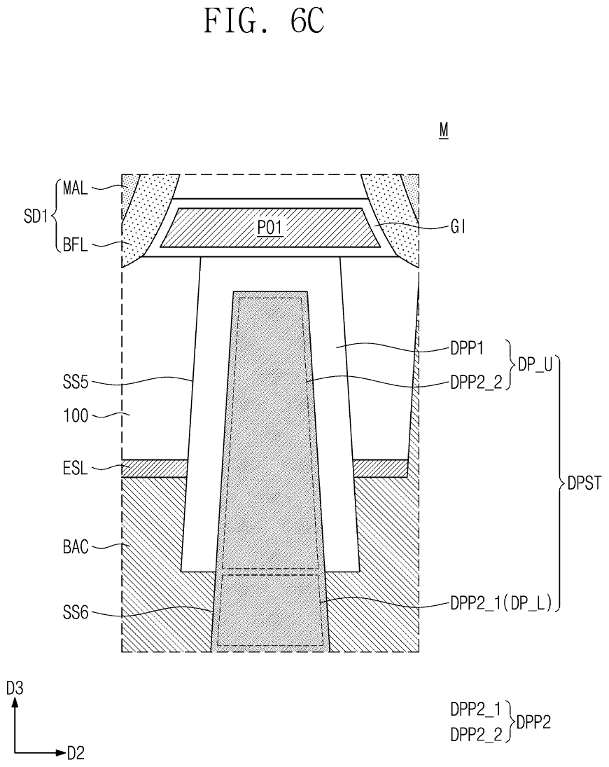

FIGS. 6A to 6C are enlarged views illustrating an embodiment and other embodiments of region M of FIG. 5A. Hereinafter, a semiconductor device according to an embodiment of the inventive concept will be described with reference to FIGS. 6A to 6C. For simplification of description, duplicate description of that described above will be omitted, and a difference from that described above will be mainly described.

Referring to FIGS. 6A to 6C, a rear surface filler structure DPST may include a lower filler portion DP_L and an upper filler portion DP_U on the lower filler portion DP_L. The lower filler portion DP_L may include a first part DPP2_1 of the second filler pattern DPP2 described above, and the upper filler portion DP_U may include a second part DPP2_2 of the second filler pattern DPP2 described above and a first filler pattern DPP1 on side surfaces and an upper surface of the second part DPP2_2. The second part DPP2_2 may be a portion of the second filler pattern DPP2 on the first part DPP2_1.

Specifically, the first part DPP2_1 may be in direct contact with a rear surface active contact BAC, and the second part DPP2_2 may be in direct contact with the first filler pattern DPP1. Sidewalls of the first filler pattern DPP1 may be in direct contact with the rear surface active contact BAC, the etch stopping layer ESL, and the substrate 100. An upper surface of the first filler pattern DPP1 may be in direct contact with a lower surface of the gate insulating film GI surrounding the first inner electrode PO1.

The first filler pattern DPP1, the second filler pattern DPP2, and the etch stopping layer ESL may include different insulating materials. The insulating materials may include SiO₂, SiN, SiOC, TiO₂, or a combination thereof. Specifically, the first filler pattern DPP1 may include at least one of SiO₂, SiN, SiOC, or TiO₂, and the second filler pattern DPP2 may include another one, among SiO₂, SiN, SiOC, and TiO₂, different from the first filler pattern DPP1.

Referring to FIG. 6A, a sidewall SS1 of the upper filler portion DP_U may have a different slope from a sidewall SS2 of the lower filler portion DP_L. For example, the sidewall SS1 of the upper filler portion DP_U may have a positive slope. The sidewall SS1 of the upper filler portion DP_U may correspond to a sidewall of the first filler pattern DPP1. The sidewall SS2 of the lower filler portion DP_L may have a negative slope.

For example, the upper filler portion DP_U may have a tapered shape in which a width thereof becomes narrower in the third direction D3, and the lower filler portion DP_L may have a tapered shape in which a width thereof becomes wider in the third direction D3. For example, the second filler pattern DPP2 of the rear surface filler structure DPST may have a width in the second direction D2 getting wider and then narrower in the third direction D3. In example embodiments, the first filler pattern DPP1 of the rear surface filler structure DPST may have a width in the second direction D2 that decreases in the third direction D3, and the second filler pattern DPP2 of the rear surface filler structure DPST may have a width in the second direction D2 that increases and then decreases in the third direction D3.

Referring to FIG. 6B, a sidewall SS3 of the upper filler portion DP_U may have a positive slope, and a sidewall SS4 of the lower filler portion DP_L may be parallel to the third direction D3 vertical to the substrate 100. That is, the upper filler portion DP_U may have a tapered shape in which a width thereof becomes narrower in the third direction D3, and the lower filler portion DP_L may have a shape of a tetragon in which a width thereof is constant in the third direction D3. For example, the rear surface filler structure DPST may have a width in the second direction D2 being constant and then getting narrower in the third direction D3. In example embodiments, the first filler pattern DPP1 of the rear surface filler structure DPST may have a width in the second direction D2 that decreases in the third direction D3, and the second filler pattern DPP2 of the rear surface filler structure DPST may have a width in the second direction D2 that is constant and then decreases in the third direction D3.

Referring to FIG. 6C, a sidewall SS5 of the upper filler portion DP_U may have the same slope as a sidewall SS6 of the lower filler portion DP_L. For example, the sidewall SS5 of the upper filler portion DP_U may have a positive slope, and the sidewall SS6 of the lower filler portion DP_L may also have a positive slope. For example, the upper filler portion DP_U may have a tapered shape in which a width thereof becomes narrower in the third direction D3, and the lower filler portion DP_L may have a tapered shape in which a width thereof becomes narrower in the third direction D3. In example embodiments, each of the first filler pattern DPP1 and the second filler pattern DPP2 of the rear surface filler structure DPST may have a width in the second direction D2 that decreases in the third direction D3.

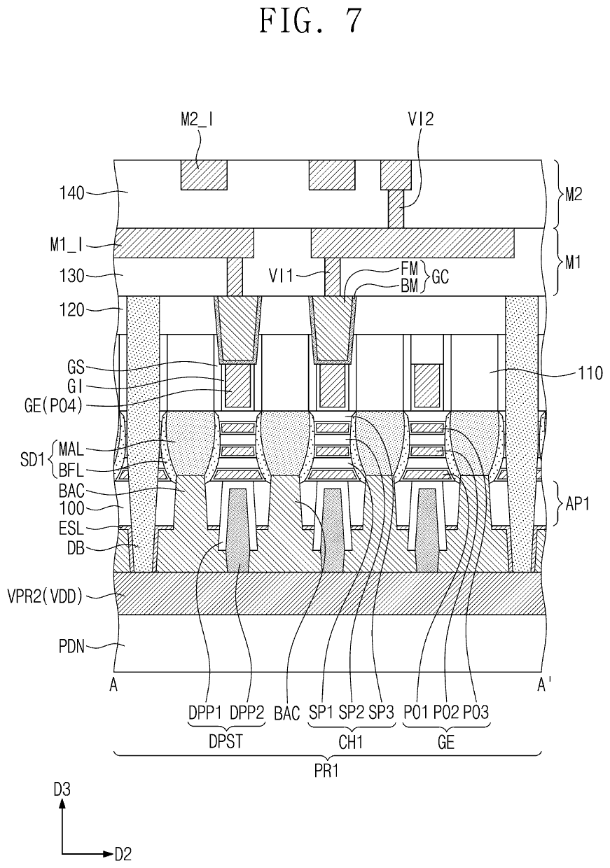

FIG. 7 is a cross-sectional view for describing a semiconductor device according to another example embodiment of FIG. 5A. Referring to FIG. 7, the rear surface active contact BAC penetrating the substrate 100 to vertically extend from the second lower power line VPR2 to the first source/drain pattern SD1 may be provided. Specifically, the rear surface active contact BAC may be disposed under the substrate 100 to vertically extend from the second lower power line VPR2 to the first source/drain pattern SD1.

The rear surface active contact BAC may have a form of a conductive column vertically and electrically connecting the second lower power line VPR2 and the first source/drain pattern SD1. The drain voltage VDD may be applied to the first source/drain pattern SD1 through the rear surface active contact BAC.

According to the present embodiment, the rear surface active contact BAC may be electrically connected to the first source/drain pattern SD1 in a unit cell not to form the upper active contact AC (see FIG. 5A). Accordingly, the upper active contact AC may not be formed on a frontside of the semiconductor device, thereby preventing a short phenomenon between the gate contact and the upper active contact. In addition, contacts may be formed on the frontside of the semiconductor device at a relatively low density, thereby improving manufacturing efficiency of the semiconductor device.

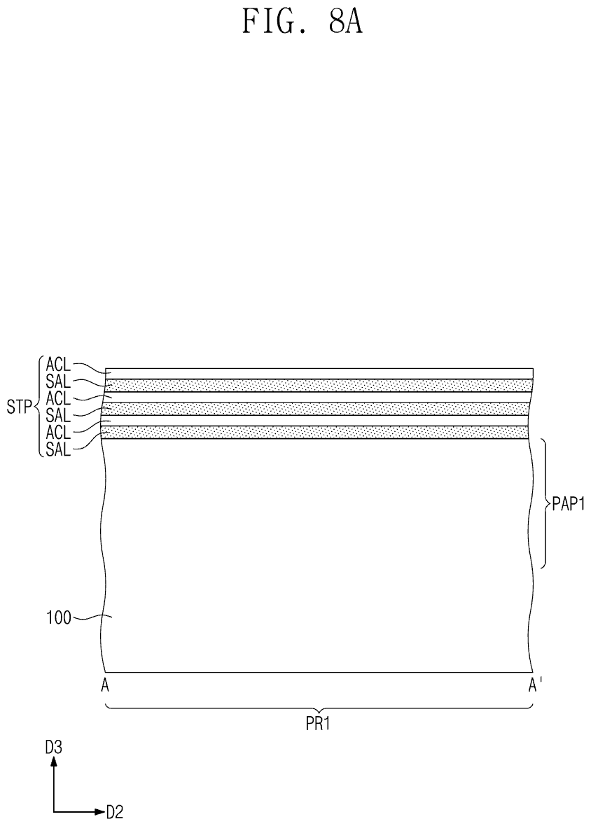

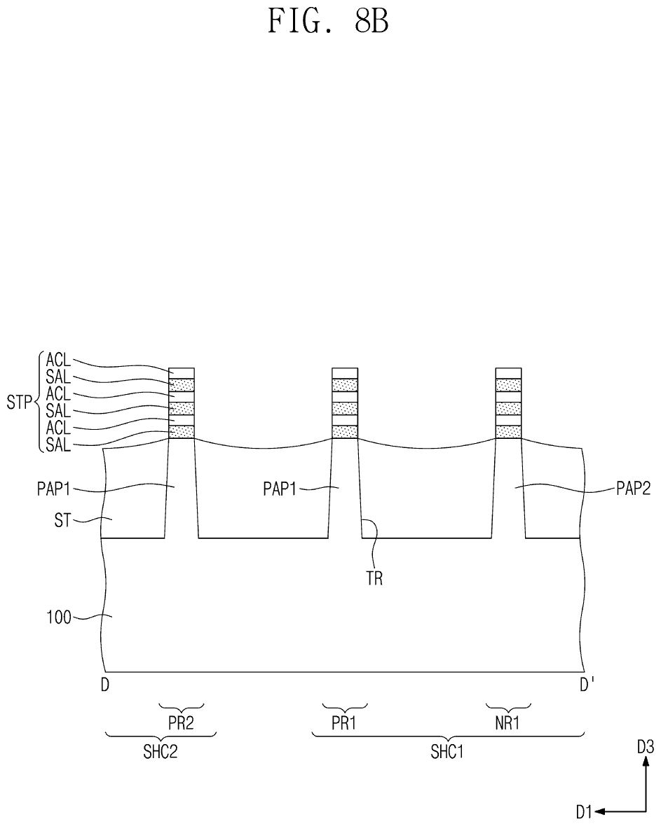

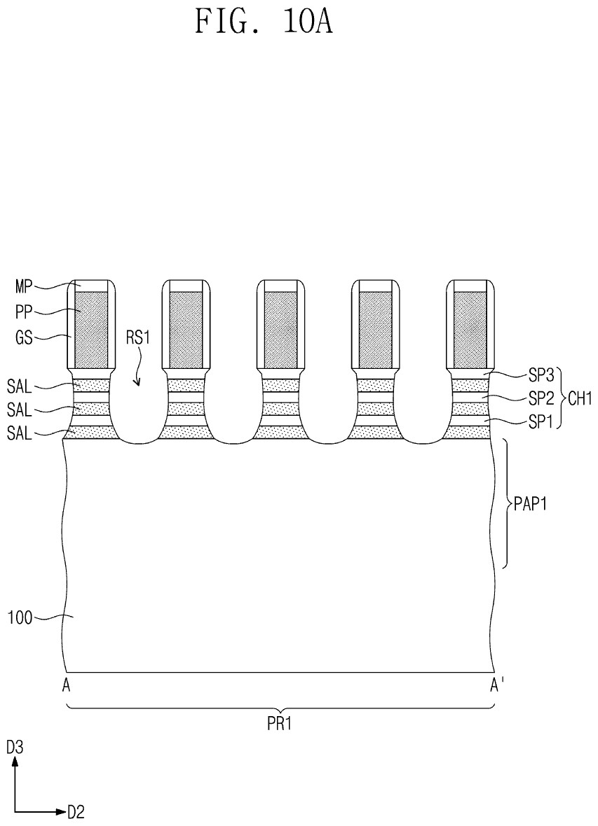

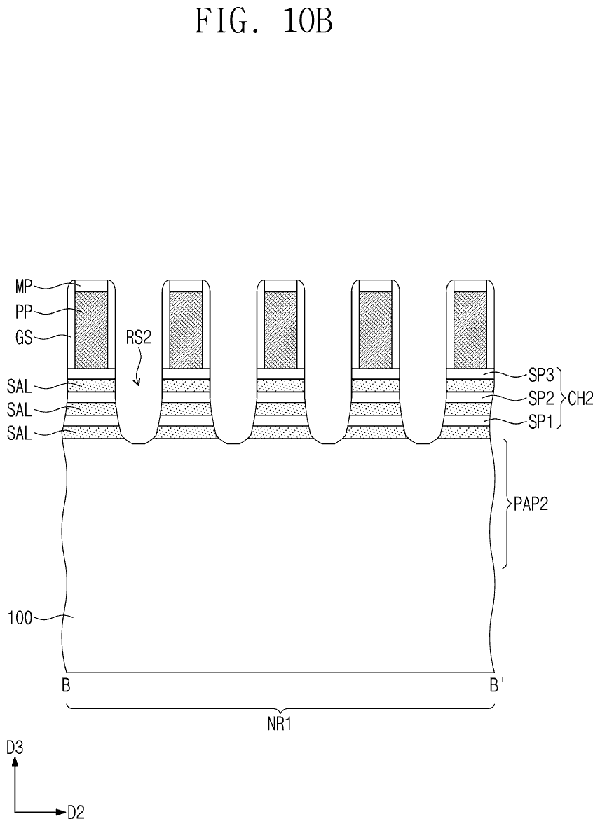

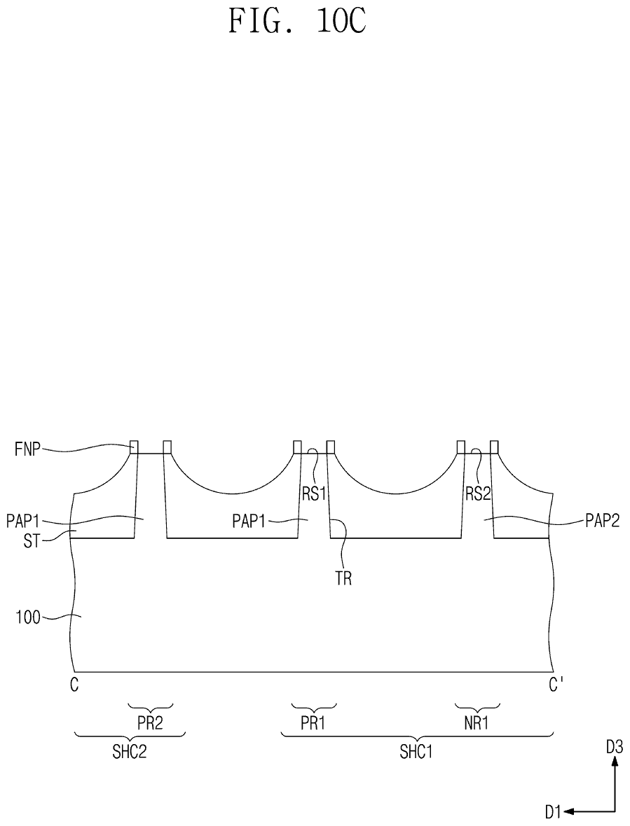

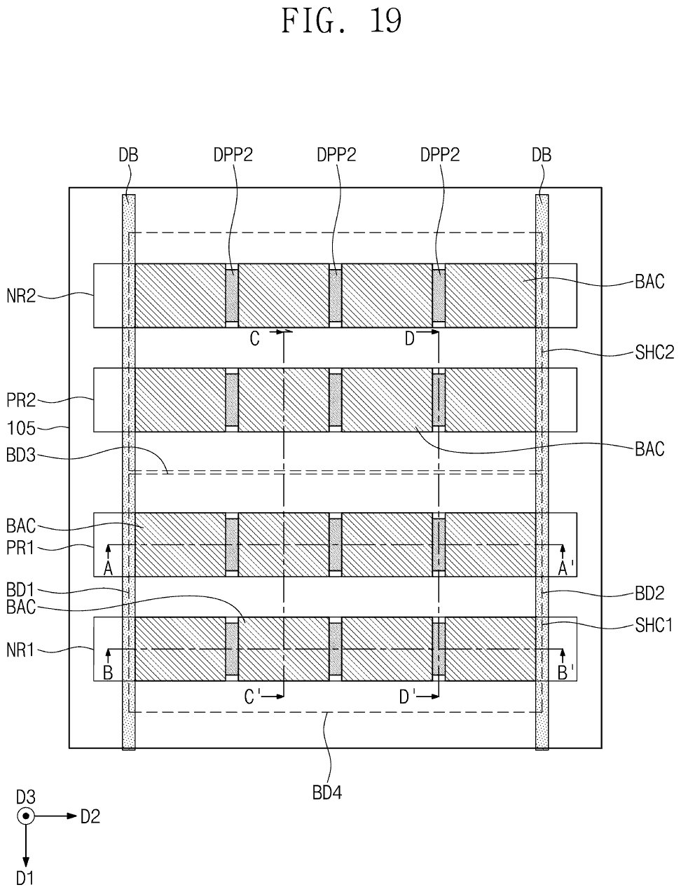

FIGS. 8A to 20D are cross-sectional views for describing a method for manufacturing a semiconductor device according to example embodiments of the inventive concept. Specifically, FIGS. 8A, 9A, 10A, 11A, 12A, 13A, 14A, 15A, 16A, 17A, 18A, and 20A are cross-sectional views corresponding to line A-A′ of FIG. 4. FIGS. 10B, 11B, 12B, 13B, 14B, 15B, 16B, 17B, 18B, and 20B are cross-sectional views corresponding to line B-B′ of FIG. 4. FIGS. 10C, 11C, 13C, 14C, 15C, 16C, 17C, 18C, and 20C are cross-sectional views corresponding to line C-C′ of FIG. 4. FIGS. 8B, 9B, 12C, 13D, 14D, 15D, 16D, 17D, 18D, and 20D are cross-sectional views corresponding to line D-D′ of FIG. 4. FIG. 19 is a plan view for describing a semiconductor device according to example embodiments.

Referring to FIGS. 8A and 8B, a semiconductor substrate 100 including first and second PMOSFET regions PR1 and PR2 and first and second NMOSFET regions NR1 and NR2 may be provided. For example, the substrate 100 may be a silicon substrate.

First semiconductor layers ACL and second semiconductor layers SAL alternately stacked may be formed on the substrate 100. The first semiconductor layers ACL may include one of silicon (Si), germanium (Ge), and silicon-germanium (SiGe), and the second semiconductor layers SAL may include another one of silicon (Si), germanium (Ge), and silicon-germanium (SiGe).

The second semiconductor layer SAL may include a material having etching selectivity for the first semiconductor layer ACL. For example, the first semiconductor layers ACL may include silicon (Si), and the second semiconductor layers SAL may include silicon-germanium (SiGe). The second semiconductor layers SAL may each have a germanium (Ge) concentration of about 10 at % to about 35 at %.

Mask patterns may be respectively formed on first and second PMOSFET regions PR1 and PR2 and first and second NMOSFET regions NR1 and NR2 of the semiconductor substrate 100. The mask pattern may have a form of a line or bar extending in the second direction D2.

A trench TR defining a first active pattern PAP1 and a second active pattern PAP2 may be formed by performing a patterning process in which the mask patterns are used as etching masks. The first active pattern PAP1 may be formed on each of the first and second PMOSFET regions PR1 and PR2. The second active pattern PAP2 may be formed on each of the first and second NMOSFET regions NR1 and NR2. In a plan view, the first and second active patterns PAP1 and PAP2 may have a form of a line extending parallel to each other in the second direction D2.

A stack pattern STP may be formed on each of the first and second active patterns PAP1 and PAP2. The stack pattern STP may further include the first semiconductor layers ACL and the second semiconductor layers SAL alternately stacked on the first and second active patterns PAP1 and PAP2. The stack pattern STP may be formed with the first and second active patterns PAP1 and PAP2 during the patterning process.

An element isolation film ST that fills the trench TR may be formed. Specifically, an insulating film covering the first and second active patterns PAP1 and PAP2 and the stack patterns STP may be formed on a frontside of the semiconductor substrate 100. The element isolation film ST may be formed by recessing the insulating film until the stack pattern STP is exposed.

The element isolation film ST may include an insulating material such as a silicon oxide film. The stack patterns STP may be exposed above the element isolation film ST. In other words, the stack patterns STP may vertically protrude above the element isolation film ST.

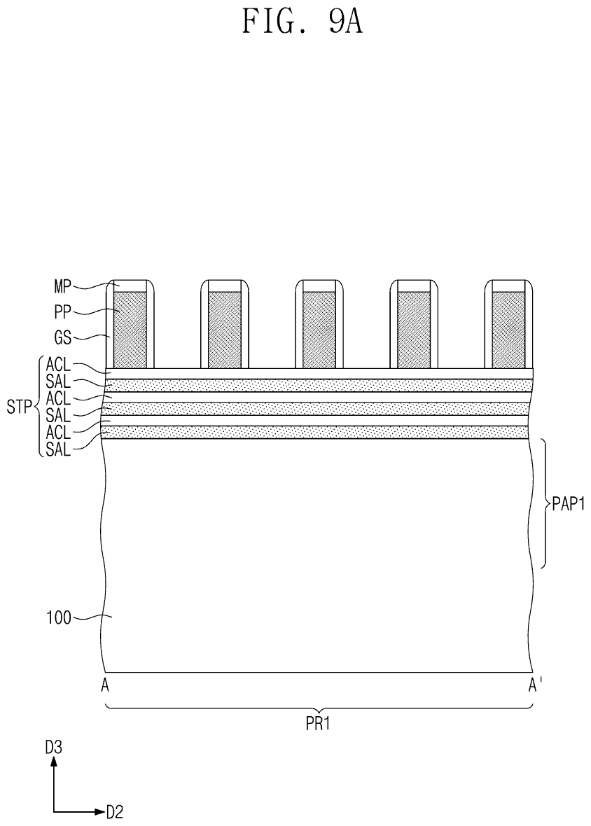

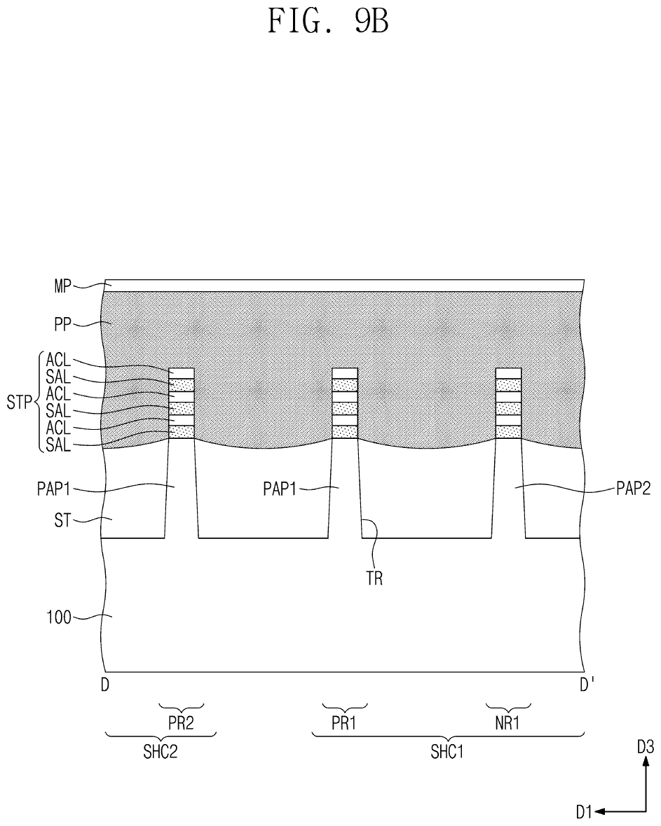

Referring to FIGS. 9A and 9B, sacrificial patterns PP crossing the stack patterns STP may be formed on the substrate 100. Each of the sacrificial patterns PP may be formed in a form of a line or bar extending in the first direction D1. The sacrificial patterns PP may be arranged with a first pitch in the second direction D2.

Specifically, forming the sacrificial patterns PP may include forming a sacrificial film on the frontside of the substrate 100, forming hard mask patterns MP on the sacrificial film, and patterning the sacrificial film by using the hard mask patterns MP as etching masks. The sacrificial film may include polysilicon.

A pair of gate spacers GS may be formed on both sidewalls of each of the sacrificial patterns PP. Forming the gate spacers GS may include conformally forming a gate spacer film on the frontside of the substrate 100, and anisotropically etching the gate spacer film. The gate spacer film may include at least one of SiCN, SiCON, or SiN. As another example, the gate spacer film may be a multi-layer including at least two of SiCN, SiCON, or SiN.

Referring to FIGS. 10A to 10C, first recesses RS1 may be formed in the stack pattern STP on the first active pattern PAP1. Second recesses RS2 may be formed in the stack pattern STP on the second active pattern PAP2. While the first and second recesses RS1 and RS2 are formed, the element isolation film ST on both sides of each of the first and second active patterns PAP1 and PAP2 may be further recessed (see FIG. 10C).

Specifically, the first recesses RS1 may be formed by etching the stack pattern STP on the first active pattern PAP1 by using the hard mask patterns MP and the gate spacers GS as etching masks. The first recess RS1 may be formed between a pair of sacrificial patterns PP. The second recesses RS2 in the stack pattern STP on the second active pattern PAP2 may be formed in the same method as forming the first recesses RS1.

Referring back to FIG. 10C, a fence pattern FNP may be formed on each of the first and second active patterns PAP1 and PAP2. The fence pattern FNP may be a portion of the residual gate spacer GS.

Referring back to FIGS. 10A to 10C, the first to third semiconductor patterns SP1, SP2, and SP3 sequentially stacked between the first recesses RS1 adjacent to each other may be respectively formed from the first semiconductor layers ACL. The first to third semiconductor patterns SP1, SP2, and SP3 sequentially stacked between the second recesses RS2 adjacent to each other may be respectively formed from the first semiconductor layers ACL. The first to third semiconductor patterns SP1, SP2, and SP3 between the first recesses RS1 adjacent to each other may constitute the first channel pattern CH1. The first to third semiconductor patterns SP1, SP2, and SP3 between the second recesses RS2 adjacent to each other may constitute the second channel pattern CH2.

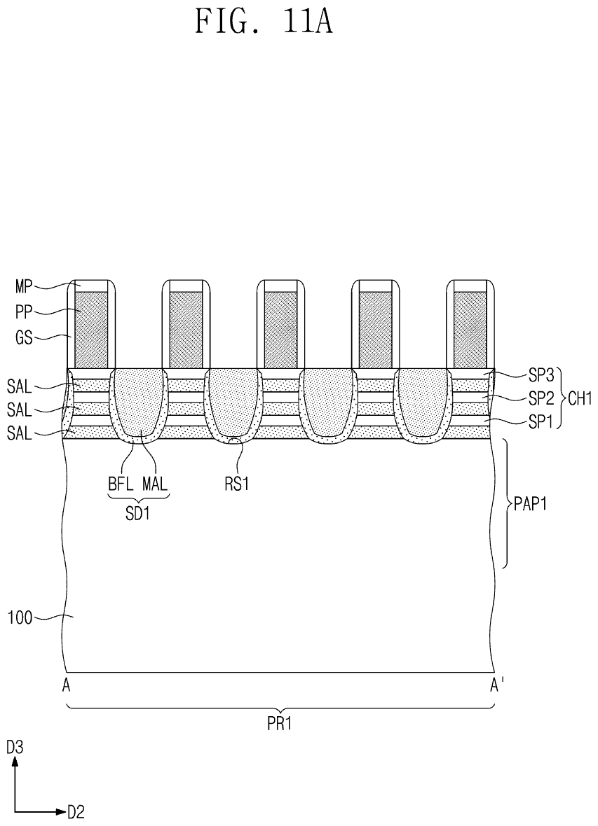

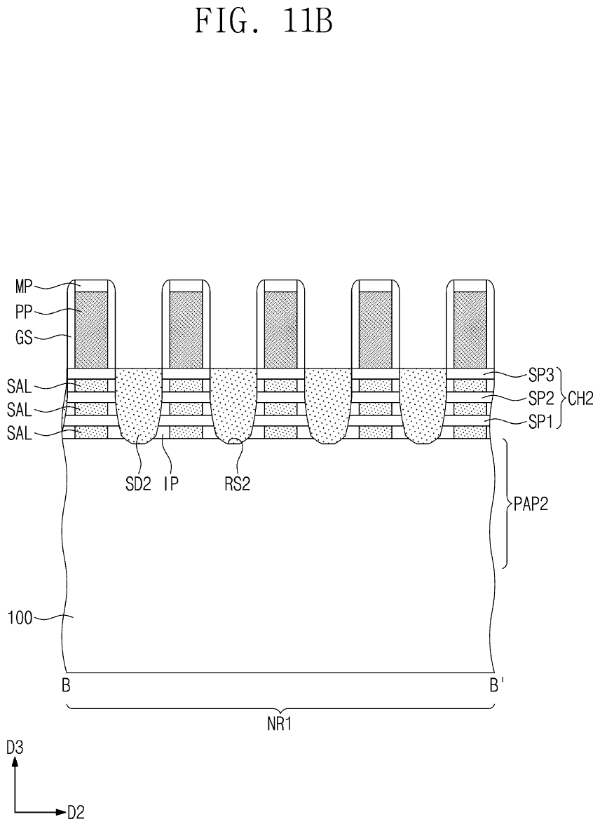

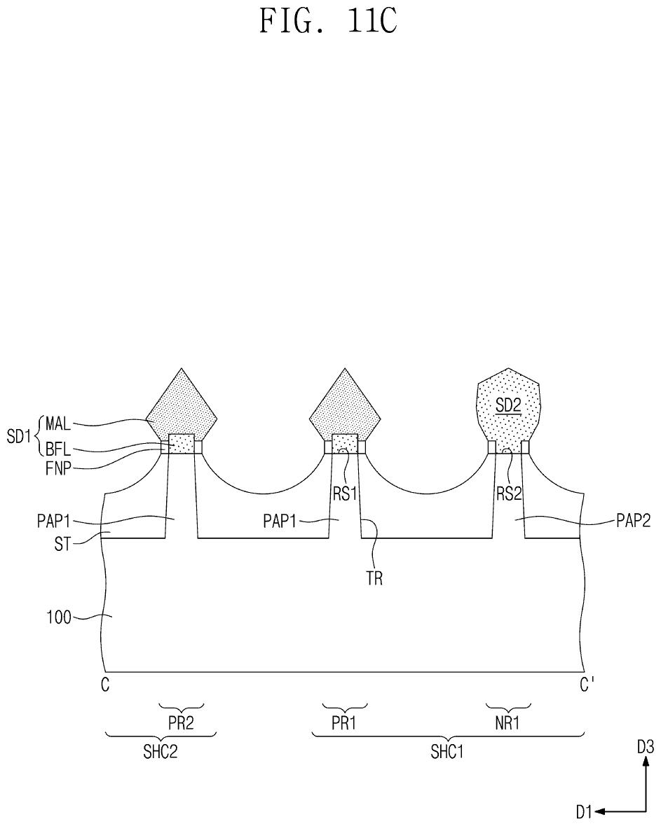

Referring to FIGS. 11A to 11C, the first source/drain patterns SD1 may be respectively formed in the first recesses RS1. Specifically, a buffer layer BFL may be formed by performing a first SEG process in which inner sidewalls of the first recess RS1 are used as seed layers. The buffer layer BFL may be grown by using, as seeds, the semiconductor substrate 100 and the first to third semiconductor patterns SP1, SP2, and SP3 exposed by the first recess RS1. For example, the first SEG process may include a chemical vapor deposition (CVD) process or a molecular beam epitaxy (MBE) process.

The buffer layer BFL may include a semiconductor element (for example, SiGe) having a greater lattice parameter than a semiconductor element of the semiconductor substrate 100. The buffer layer BFL may contain germanium (Ge) having a relatively low concentration. According to another embodiment of the inventive concept, the buffer layer BFL may contain only silicon (Si) except for germanium (Ge). The buffer layer BFL may have a germanium (Ge) concentration of 0 at % to about 30 at %.

A main layer MAL may be formed by performing a second SEG process on the buffer layer BFL. The main layer MAL may be formed to completely or almost fill the first recess RS1. The main layer MAL may contain germanium (Ge) having a relatively high concentration. For example, the main layer MAL may have a germanium (Ge) concentration of about 30 at % to about 70 at %.

According to an embodiment of the inventive concept, a capping layer may be formed by performing a third SEG process on the main layer MAL. The capping layer may include silicon (Si). The capping layer may have a silicon (Si) concentration of about 98 at % to about 100 at %.

While the buffer layer BFL and the main layer MAL are formed, an impurity (for example, boron, gallium, or indium) causing the first source/drain pattern SD1 to become a P-type may be in-situ injected. As another example, after the first source/drain pattern SD1 is formed, the impurity may be injected into the first source/drain pattern SD1.

The second source/drain patterns SD2 may be respectively formed in the second recesses RS2. Specifically, the second source/drain pattern SD2 may be formed by performing a selective epitaxial growth (SEG) process in which inner sidewalls of the second recess RS2 are used as seed layers. For example, the second source/drain pattern SD2 may include the same semiconductor element (for example, Si) as the substrate 100.

While the second source/drain pattern SD2 is formed, an impurity (for example, phosphorous, arsenic, or antimony) causing the second source/drain pattern SD2 to become an N-type may be in-situ injected. As another example, after the second source/drain pattern SD2 is formed, the impurity may be injected into the second source/drain pattern SD2.

According to an embodiment of the inventive concept, inner spacers IP may be formed by partially replacing the second semiconductor layer SAL exposed through the second recess RS2 with an insulating material before the second source/drain pattern SD2 is formed. As a result, the inner spacers IP may be respectively formed between the second source/drain pattern SD2 and the second semiconductor layers SAL.

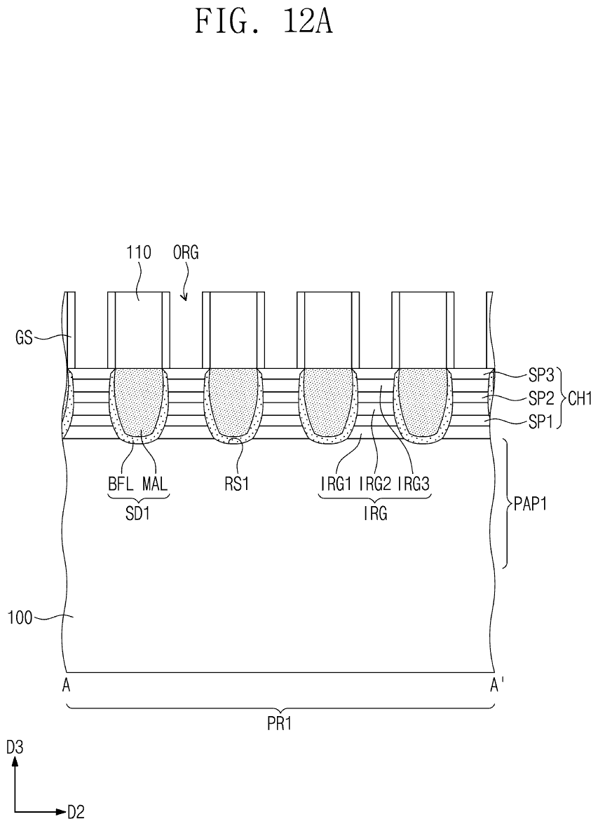

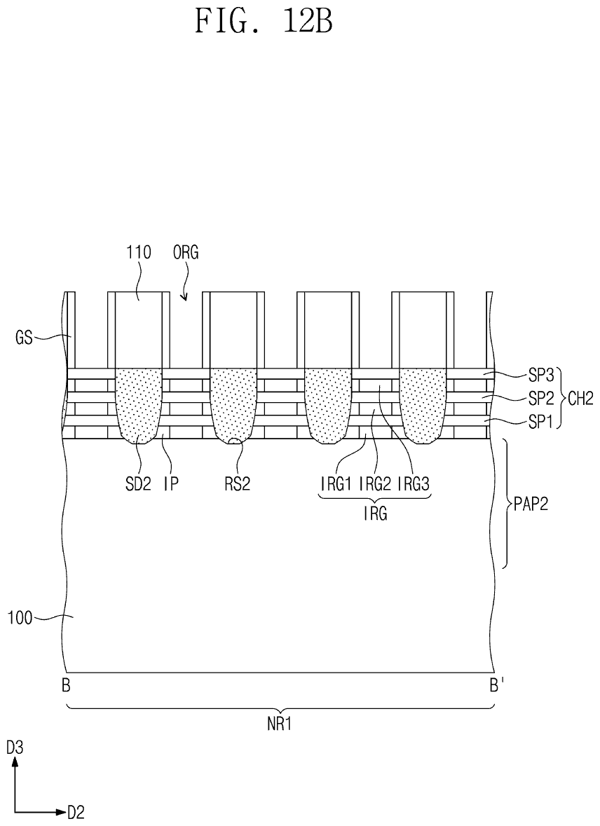

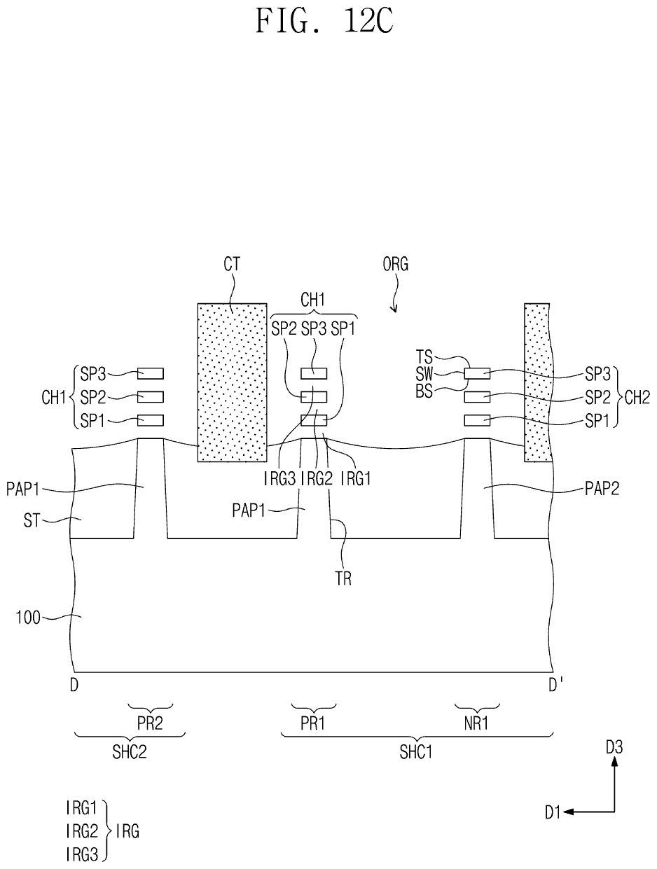

Referring to FIGS. 12A to 12C, a first interlayer insulating layer 110 covering the first and second source/drain patterns SD1 and SD2, the hard mask patterns MP and the gate spacers GS may be formed. For example, the first interlayer insulating layer 110 may include a silicon oxide film.

The first interlayer insulating layer 110 may be planarized until upper surfaces of the sacrificial patterns PP are exposed. Planarization of the first interlayer insulating layer 110 may be performed by using a chemical mechanical polishing (CMP) or etch back process. The hard mask patterns MP may be completely removed during the planarization process. As a result, an upper surface of the first interlayer insulating layer 110 may be coplanar with the upper surfaces of the sacrificial patterns PP and upper surfaces of the gate spacers GS.

One region of the sacrificial pattern PP may be selectively opened by using a photolithography process. For example, a region of the sacrificial pattern PP on the third and fourth boundaries BD3 and BD4 of the first single height cell SHC1 may be opened. The opened region of the sacrificial pattern PP may be selectively etched and removed. A gate cutting pattern CT may be formed by filling, with an insulating material, a space in which the sacrificial pattern PP is removed (see FIG. 12C).

The exposed sacrificial patterns PP may be selectively removed. An outer region ORG exposing the first and second channel patterns CH1 and CH2 may be formed by removing the sacrificial patterns PP (see FIG. 12C). Removing the sacrificial patterns PP may include wet etching using etchant that selectively etches polysilicon.

The second semiconductor layers SAL exposed through the outer region ORG may be selectively removed to form inner regions IRG (see FIGS. 12A and 12B). Specifically, the first to third semiconductor patterns SP1, SP2, and SP3 may be left and only the second semiconductor layers SAL may be removed by performing an etching process of selectively etching the second semiconductor layers SAL. The etching process may have a high etch rate with respect to silicon-germanium having a relatively high germanium concentration. For example, the etching process may have a high etch rate with respect to silicon-germanium having a germanium concentration more than about 10 at %.

The second semiconductor layers SAL on the first and second PMOSFET regions PR1 and PR2 and the first and second NMOSFET regions NR1 and NR2 may be completely removed during the etching process. The etching process may be wet etching. An etching material used in the etching process may rapidly remove the second semiconductor layer SAL having a relatively high germanium concentration. Meanwhile, the first source/drain pattern SD1 on the first and second PMOSFET regions PR1 and PR2 may be protected during the etching process by the buffer layer BFL having a relatively low germanium concentration.

Referring back to FIG. 12C, only the stacked first to third semiconductor patterns SP1, SP2, and SP3 may remain on each of the first and second active patterns PAP1 and PAP2 by selectively removing the second semiconductor layers SAL. First to third inner regions IRG1, IRG2, and IRG3 may be respectively formed through regions in which the second semiconductor layers SAL are removed. Specifically, a first inner region IRG1 may be formed between the active pattern PAP1 or PAP2 and the first semiconductor pattern SP1, a second inner region IRG2 may be formed between the first semiconductor pattern SP1 and the second semiconductor pattern SP2, and a third inner region IRG3 may be formed between the second semiconductor pattern SP2 and the third semiconductor pattern SP3.

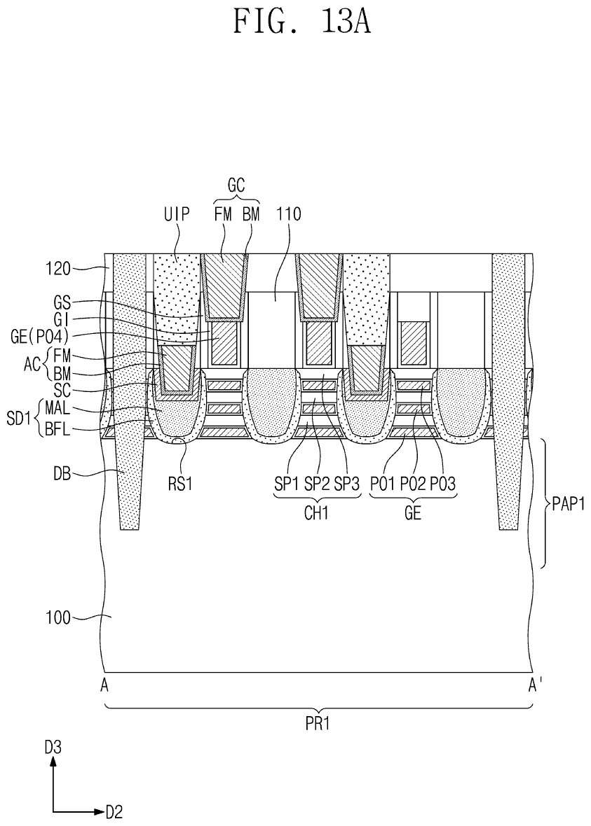

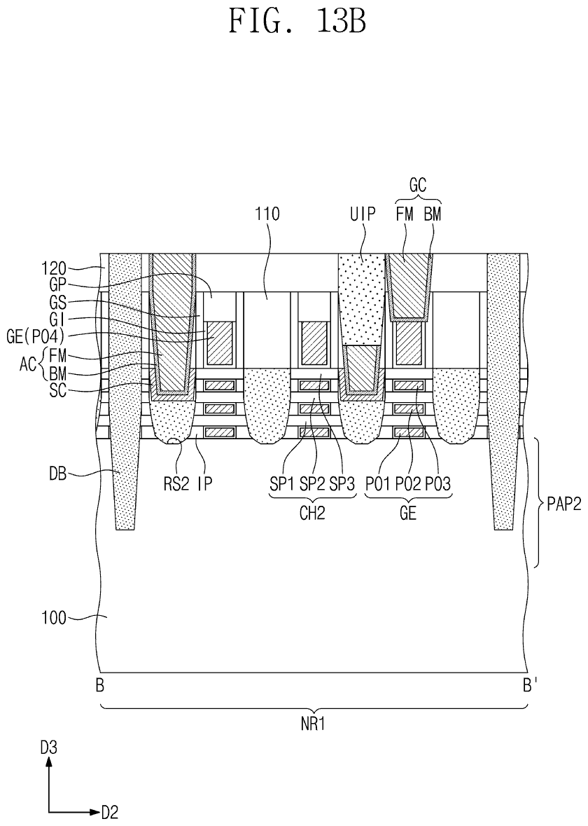

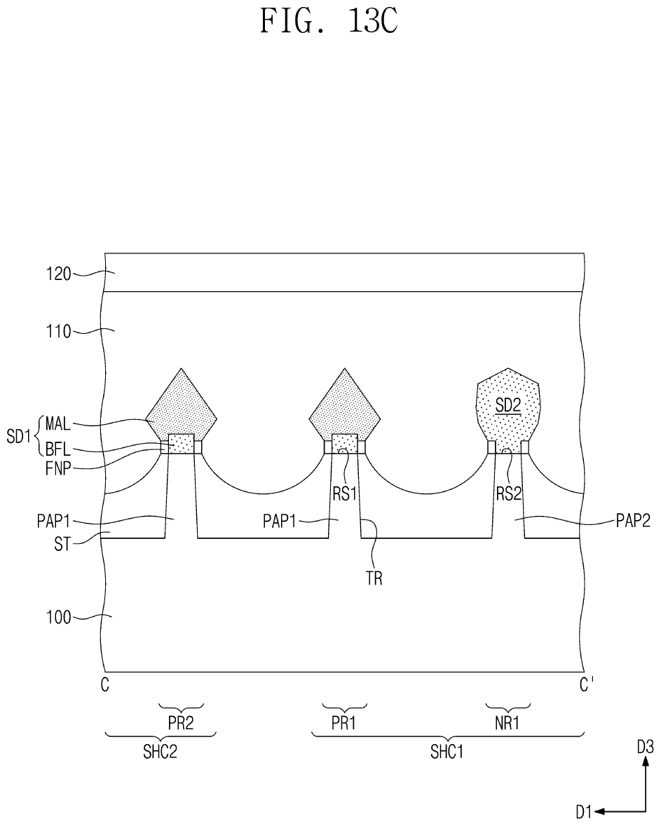

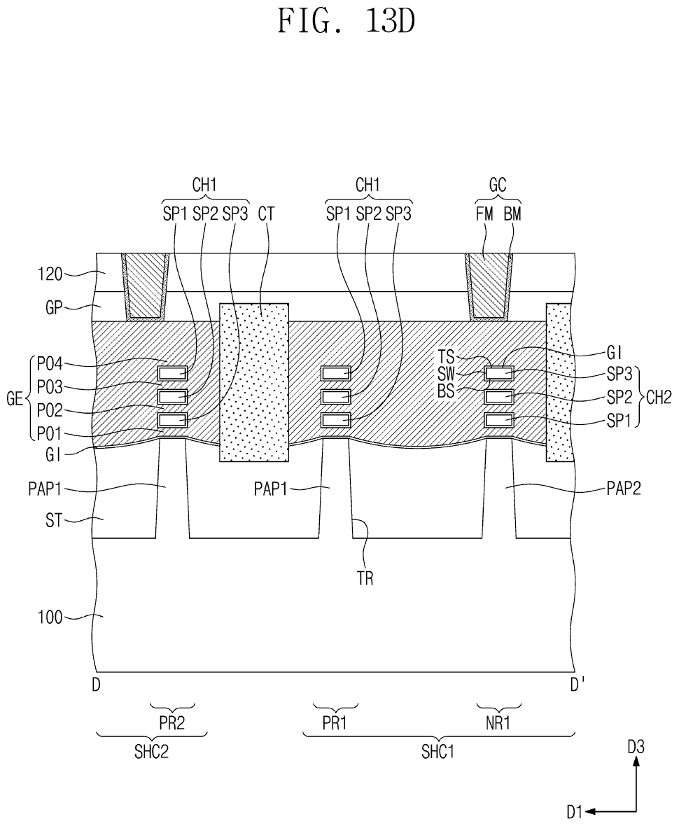

Referring to FIGS. 13A to 13D, a gate insulating film GI may be conformally formed on the exposed first to third semiconductor patterns SP1, SP2, and SP3. A gate electrode GE may be formed on the gate insulating film GI. The gate electrode GE may include first to third inner electrodes PO1, PO2, and PO3 respectively formed in the first to third inner regions IRG1, IRG2, and IRG3, and an outer electrode PO4 formed in the outer region ORG.

The gate electrode GE may be recessed to reduce a height thereof. Upper portions of the gate cutting patterns CT may be slightly recessed while the gate electrode GE is recessed. A gate capping pattern GP may be formed on the recessed gate electrode GE. The gate capping pattern GP may cover the gate electrode GE and the gate cutting pattern CT.

A second interlayer insulating layer 120 may be formed on the first interlayer insulating layer 110. The second interlayer insulating layer 120 may include a silicon oxide film. An upper active contact AC penetrating the first and second interlayer insulating layers 110 and 120 to be electrically connected to at least one of the first or second source/drain pattern SD1 or SD2 may be formed. A gate contact GC penetrating the second interlayer insulating layer 120 and the gate capping pattern GP to be electrically connected to the gate electrode GE may be formed.

Forming each of the upper active contact AC and the gate contact GC may include forming a barrier pattern BM and forming a conductive pattern FM on the barrier pattern BM. The barrier pattern BM may be conformally formed, and may include a metal film/metal nitride film. The conductive pattern FM may include metal having low resistance.

Referring back to FIGS. 4 and 5A to 5D, a third interlayer insulating layer 130 may be formed on the upper active contacts AC and the gate contacts GC. A first metal layer M1 may be formed in the third interlayer insulating layer 130. The first metal layer M1 may include a first line M1_I electrically connected to at least one of the upper active contacts AC or the gate contacts GC. A fourth interlayer insulating layer 140 may be formed on the third interlayer insulating layer 130. A second metal layer M2 may be formed in the fourth interlayer insulating layer 140.

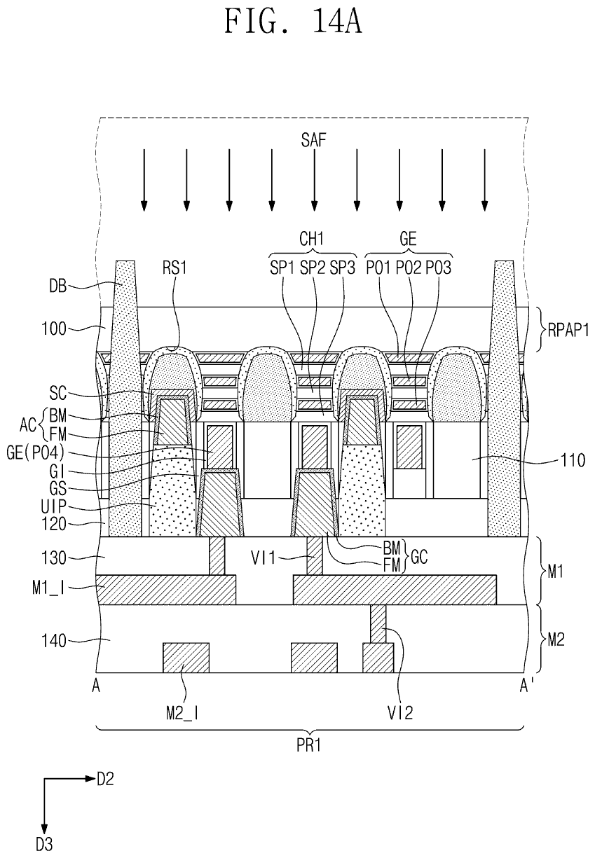

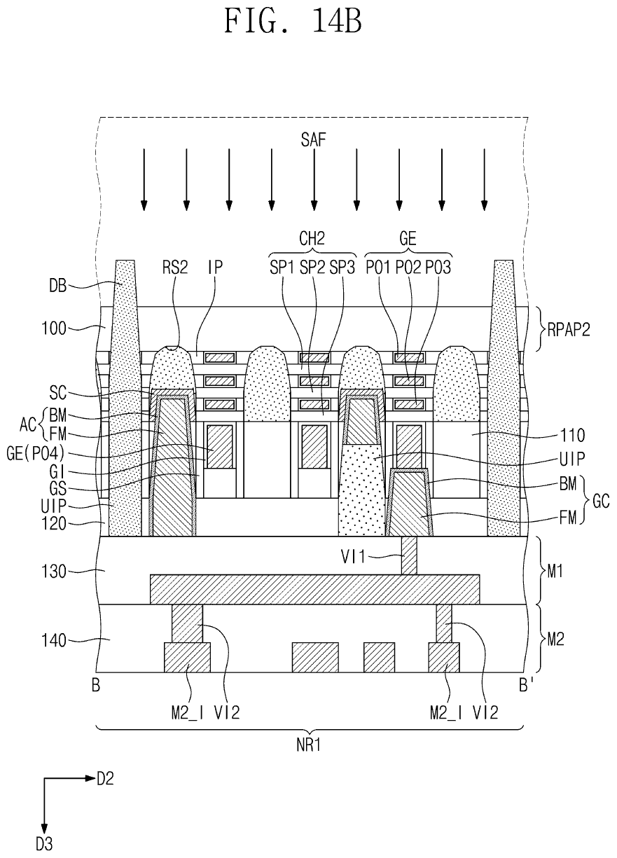

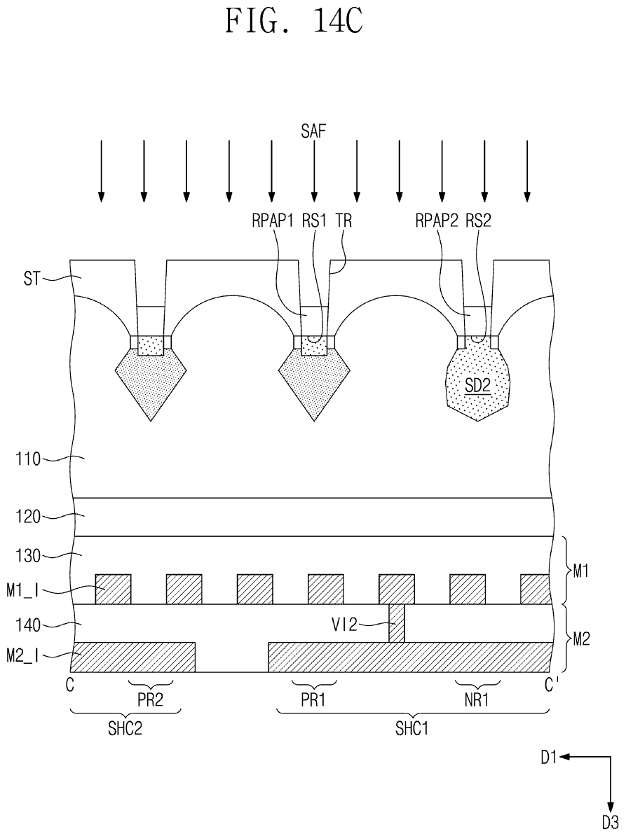

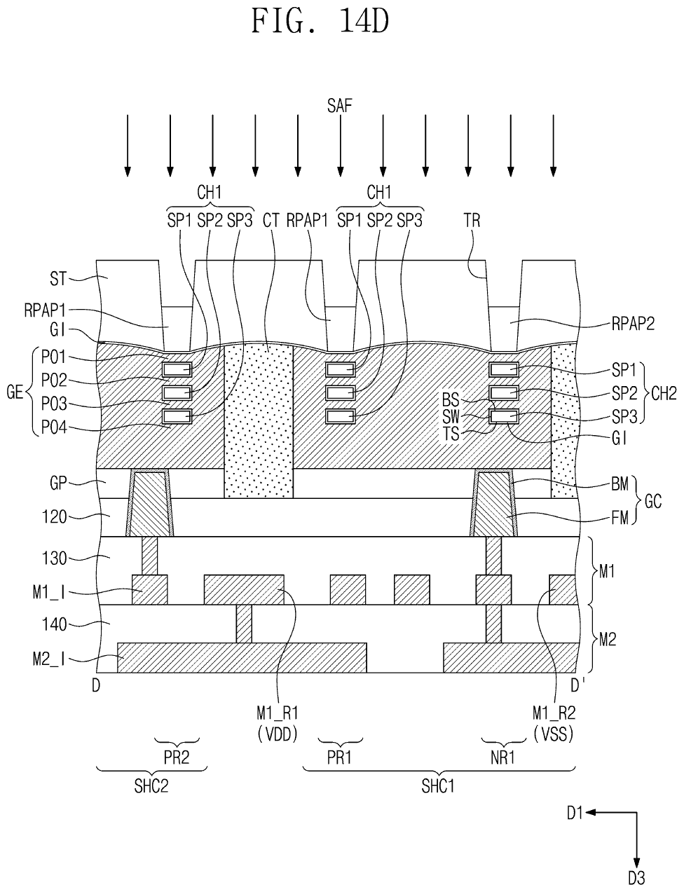

After a BEOL process is completed, the semiconductor substrate 100 described with reference to FIGS. 8A to 13D may be turned upside down. Since the semiconductor substrate 100 is turned upside down, hereinafter, in describing with reference to FIGS. 14A to 20D, ‘an upper surface’ and ‘an upper portion’ may respectively mean ‘a lower surface’ and ‘a lower portion’ from a point of view of a completely manufactured three-dimensional semiconductor device described with reference to FIGS. 5A to 5D, and ‘a lower surface’ and ‘a lower portion’ may respectively mean ‘an upper surface’ and ‘an upper portion’ from the point of view of the completely manufactured three-dimensional semiconductor device described with reference to FIGS. 5A to 5D.

Referring to FIGS. 14A to 14D, after the BEOL process is completed, the substrate 100 may be turned to expose a bottom surface of the substrate 100. The exposed substrate 100 may be partially removed.

According to an embodiment of the inventive concept, partially removing the substrate 100 may include performing a planarization process SAF on the bottom surface of the substrate 100 to reduce a thickness of the substrate 100, and performing a cleaning process of selectively removing silicon (Si) on the substrate 100. The cleaning process may be performed until an upper surface and side surfaces of an isolation structure DB are partially exposed.

A first residual active pattern RPAP1 may be formed in a region in which the first active pattern PAP1 is present by partially removing the substrate 100. A second residual active pattern RPAP2 may be formed in a region in which the second active pattern PAP2 is present by partially removing the substrate 100 (see FIGS. 14A and 14B).

The first and second residual active patterns RPAP1 and RPAP2 may be formed on the first and second source/drain patterns SD1 and SD2 by partially removing the substrate 100. The element isolation film ST may not be removed by performing the cleaning process of selectively removing silicon (see FIG. 14C).

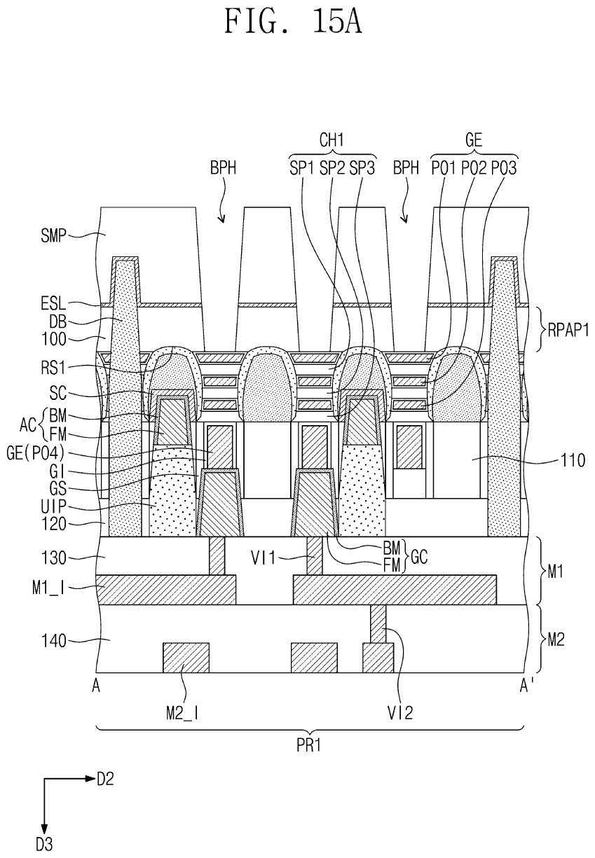

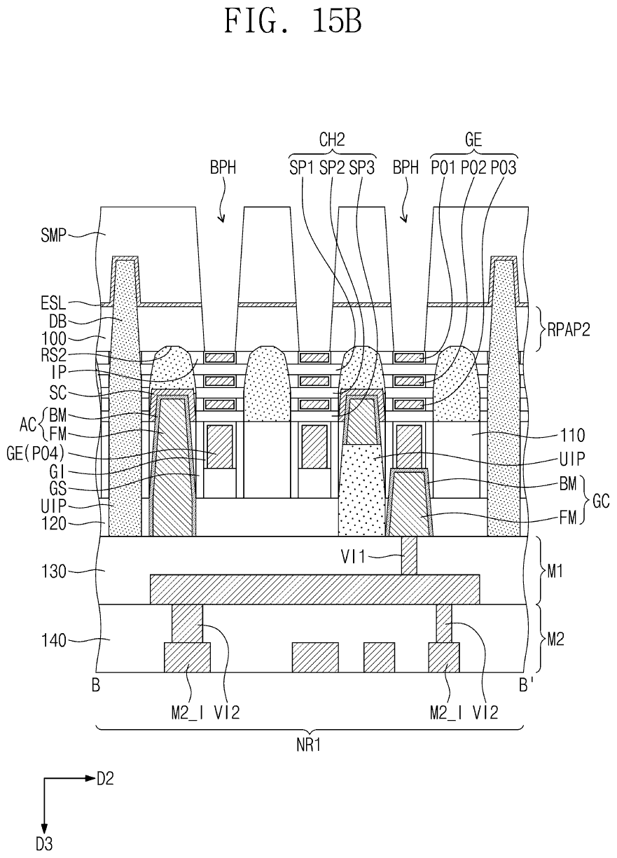

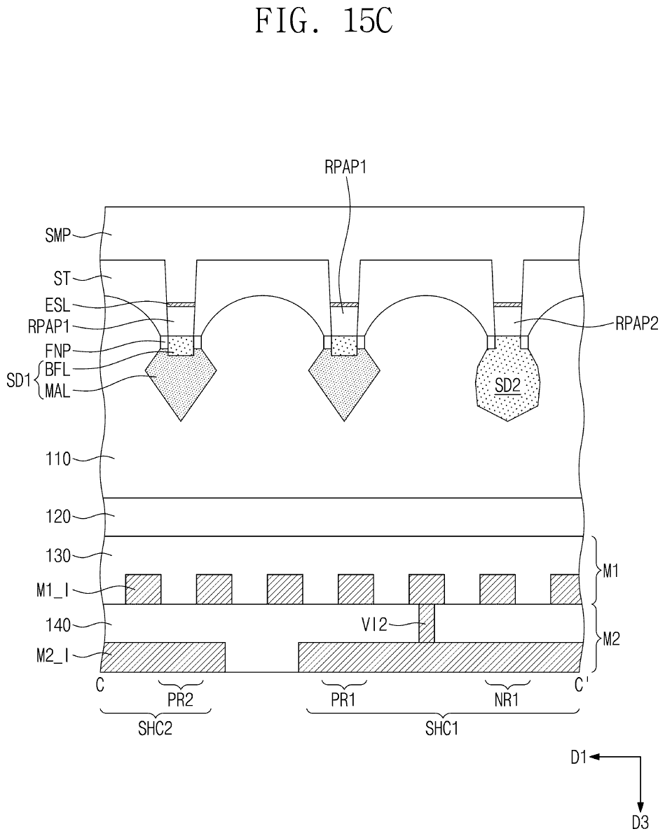

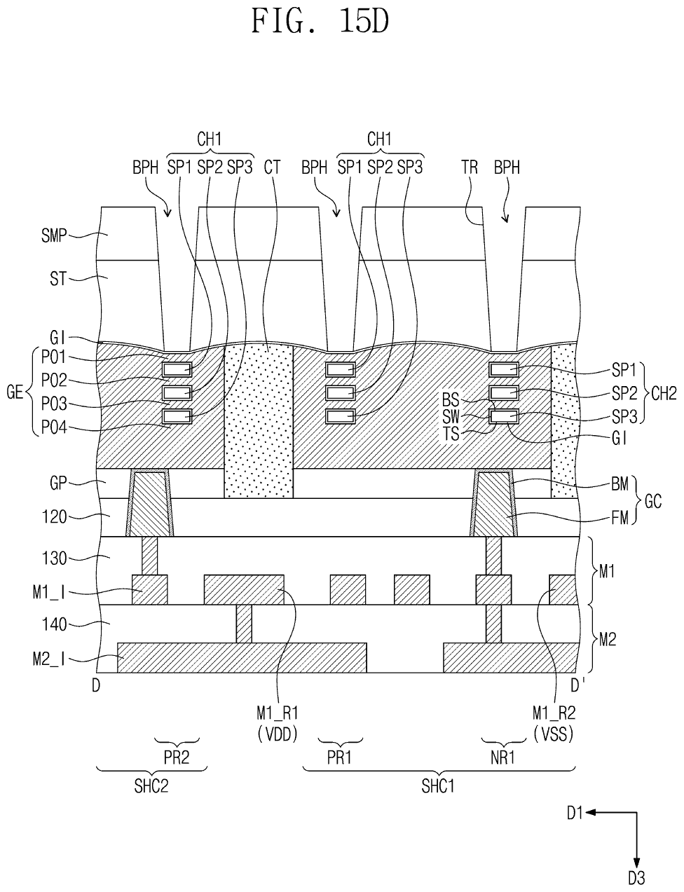

Referring to FIGS. 15A to 15D, an etch stopping layer ESL may be conformally formed on the bottom surface of the etched substrate 100. The etch stopping layer ESL may include a different material from the substrate 100. The etch stopping layer ESL may cover a bottom surface and sidewalls of the isolation structure DB, but an embodiment of the inventive concept is not limited thereto. The etch stopping layer ESL may be a multi-layered film.

A first mold film SMP may be formed on the etch stopping layer ESL formed by partially removing the substrate 100. The first mold film SMP may include at least one of an amorphous silicon film, an amorphous carbon film, a spin-on-hardmask (SOH) film, or a spin-on-carbon (SOC) film. For example, the first mold film SMP may be formed through a photolithography process. Rear surface holes BPH may be formed by performing an anisotropic etching process or a dry etching process on the substrate 100 by using the first mold film SMP as an etching mask. The rear surface holes BPH may expose an upper surface of the gate insulating film GI surrounding the first inner electrode PO1.

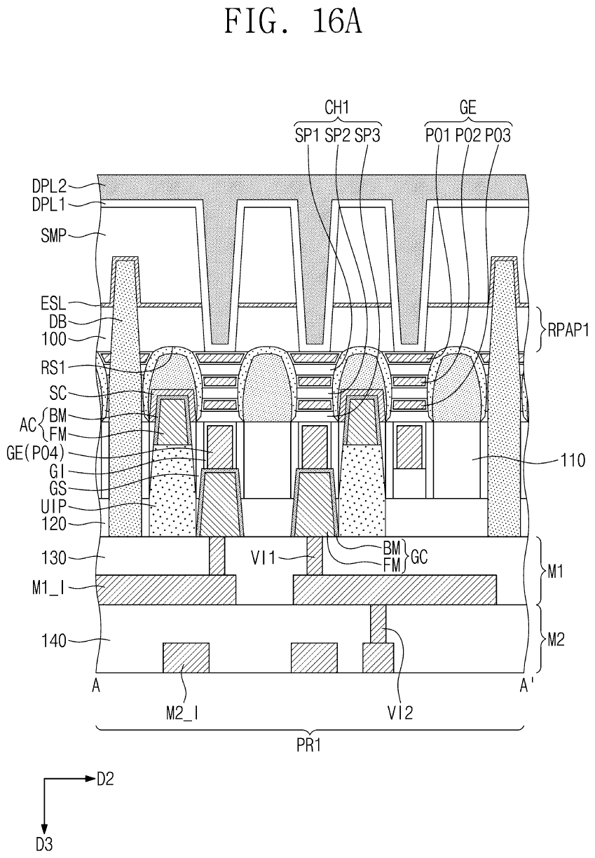

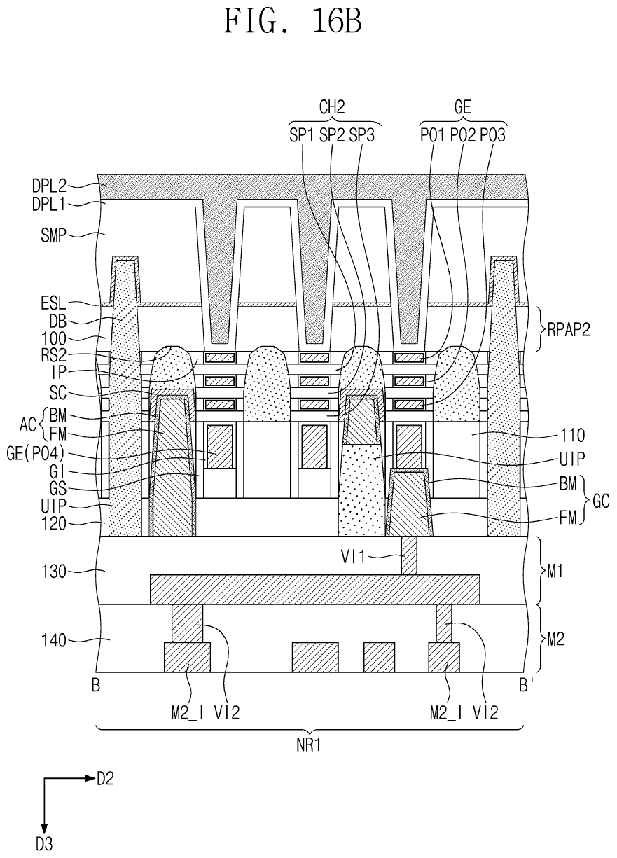

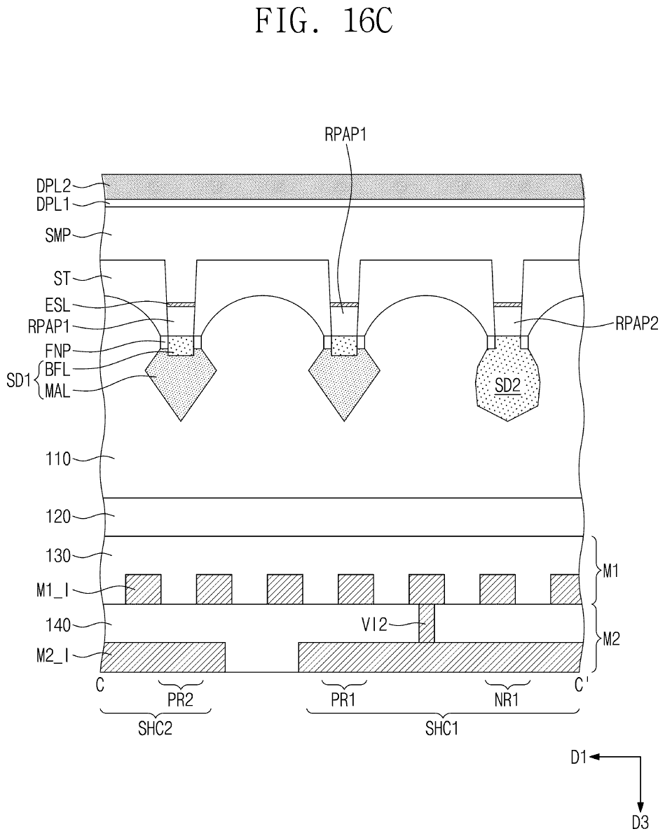

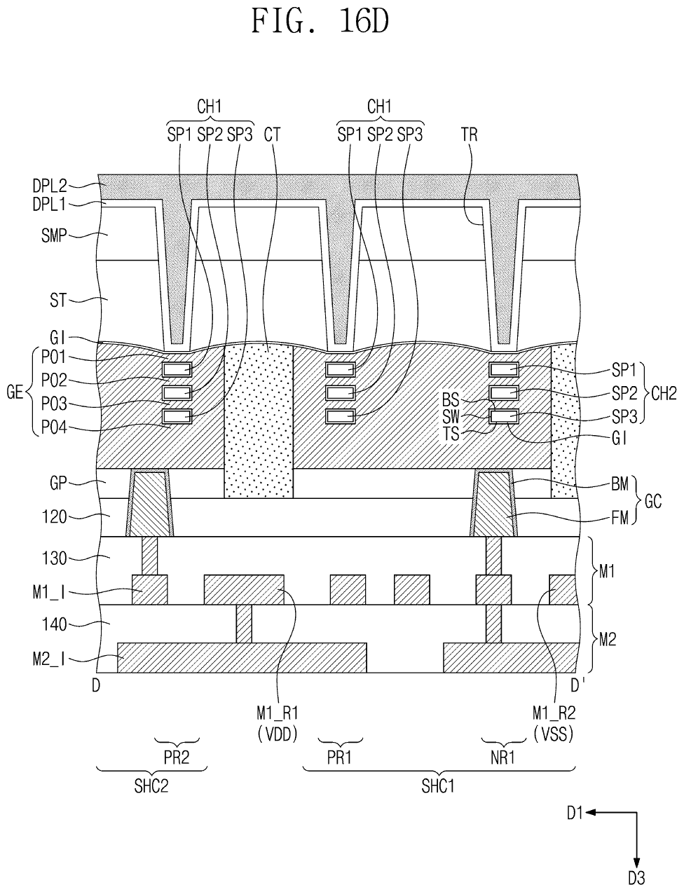

Referring to FIGS. 16A to 16D, a first filler film DPL1 and a second filler film DPL2 may be sequentially formed on the rear surface holes BPH and the first mold film SMP. The first filler film DPL1 may be conformally formed by performing a chemical vapor deposition (CVD) process on the rear surface holes BPH and the first mold film SMP. The second filler film DPL2 may be formed so as to completely fill the rear surface holes BPH by performing a chemical vapor deposition (CVD) process on the first filler film DPL1.

The first filler film DPL1 and the second filler film DPL2 may include different insulating materials. The insulating materials may include SiO₂, SiN, SiOC, TiO₂, or a combination thereof. Specifically, the first filler film DPL1 may include at least one of SiO₂, SiN, SiOC, or TiO₂, and the second filler film DPL2 may include another one, among SiO₂, SiN, SiOC, and TiO₂, different from the first filler film DPL1. As another example, the first and second filler films DPL1 and DPL2 may include the same insulating material as each other.

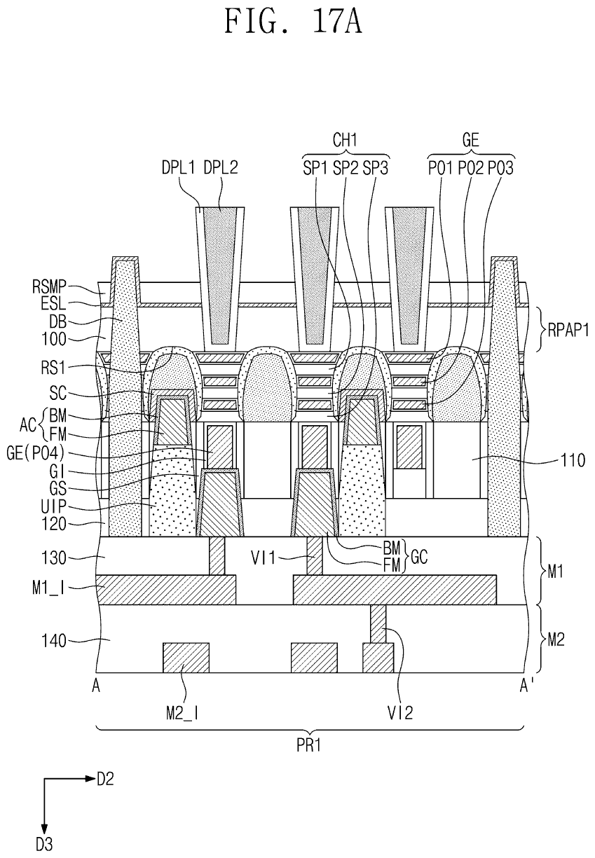

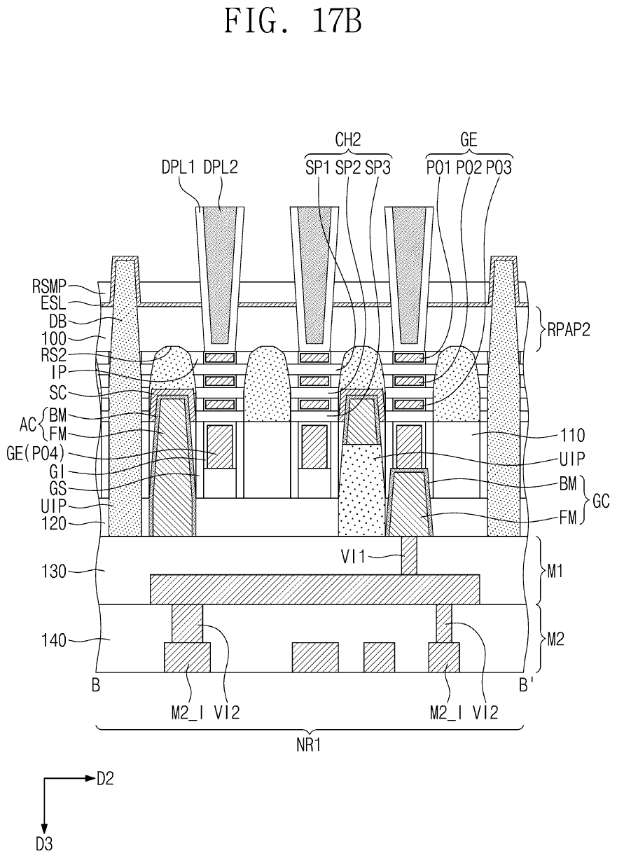

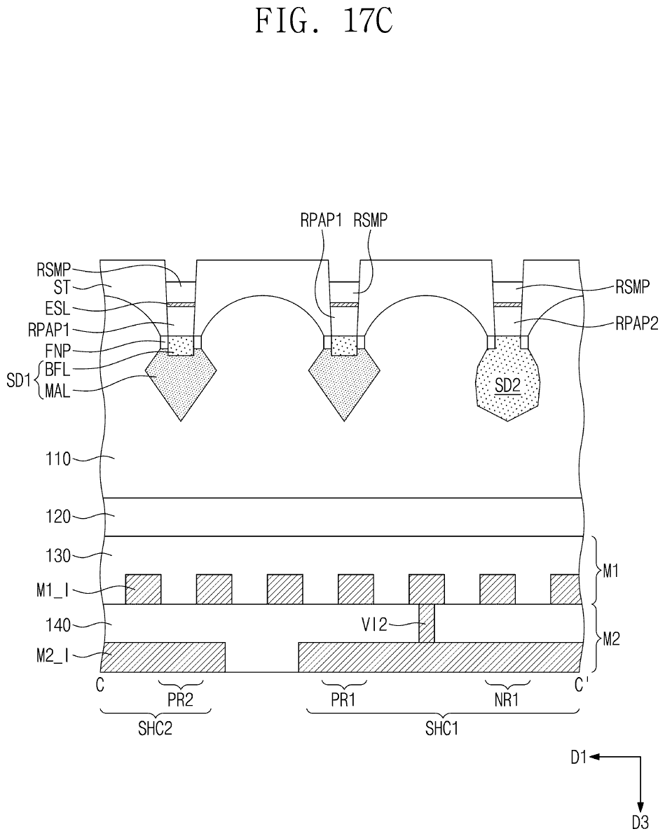

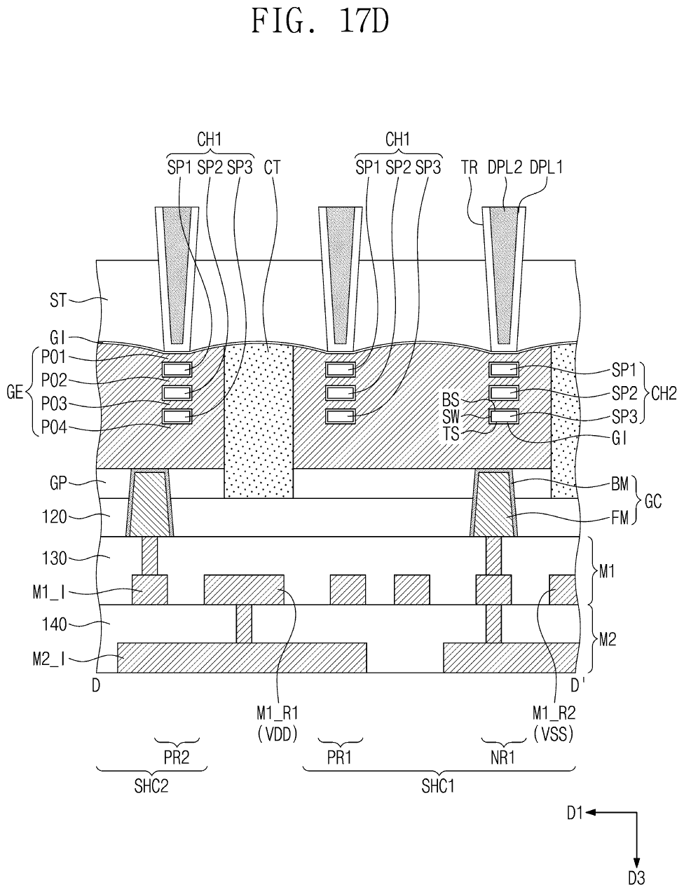

Referring to FIGS. 17A to 17D, a planarization process may be performed on the first and second filler films DPL1 and DPL2. The planarization process may be a chemical mechanical polishing (CMP) process. The planarization process may be performed by using the first mold film SMP as a stop layer until an upper surface of the first mold film SMP is exposed. After the planarization process, the upper surface of the first mold film SMP and upper surfaces of the first and second filler films DPL1 and DPL2 may be substantially coplanar with each other.

A SOH recess or etch back process may be performed on the first mold film SMP. The recess process may be an isotropic etching process or wet etching process. A residual mold film RSMP may be formed in a region in which the first mold film SMP is present by partially removing the first mold film SMP. Portions of side surfaces of the first filler film DPL1 and the etch stopping layer ESL on the isolation structure DB may be exposed by performing the recess process. In addition, an upper surface of the element isolation film ST may be exposed by performing the recess process (see FIG. 17D).

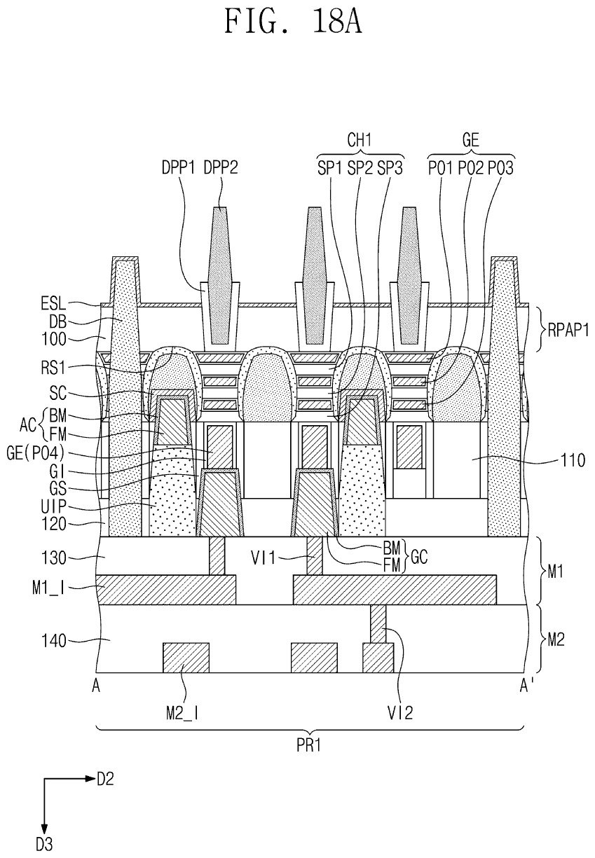

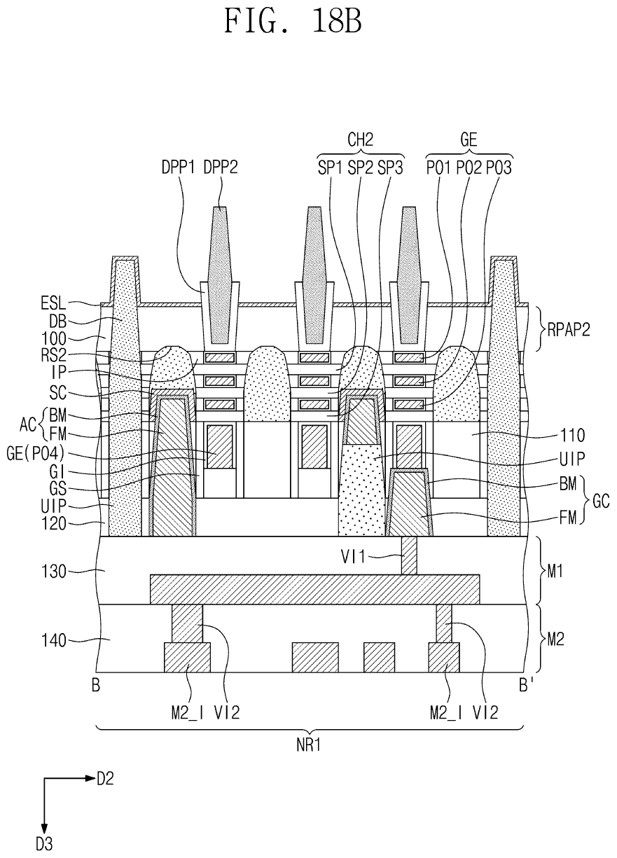

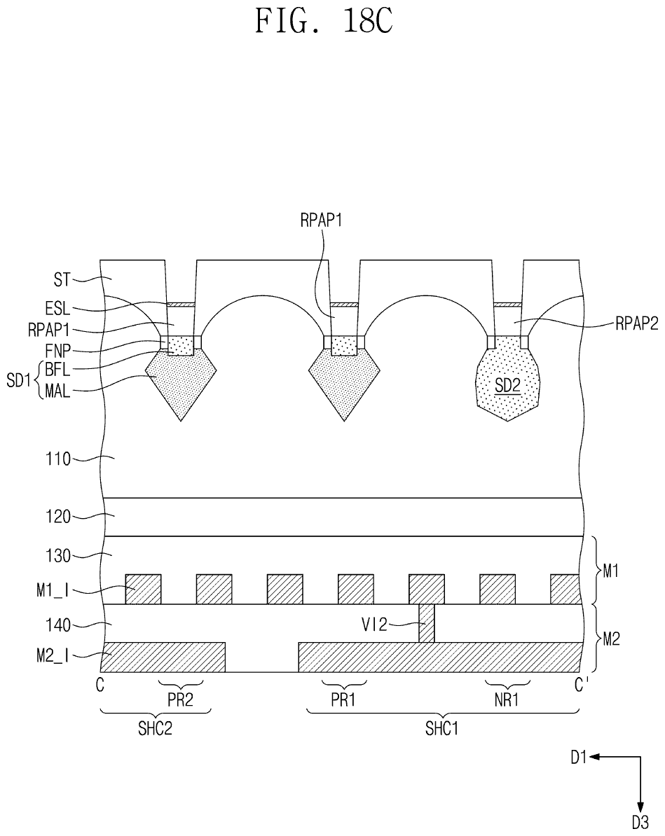

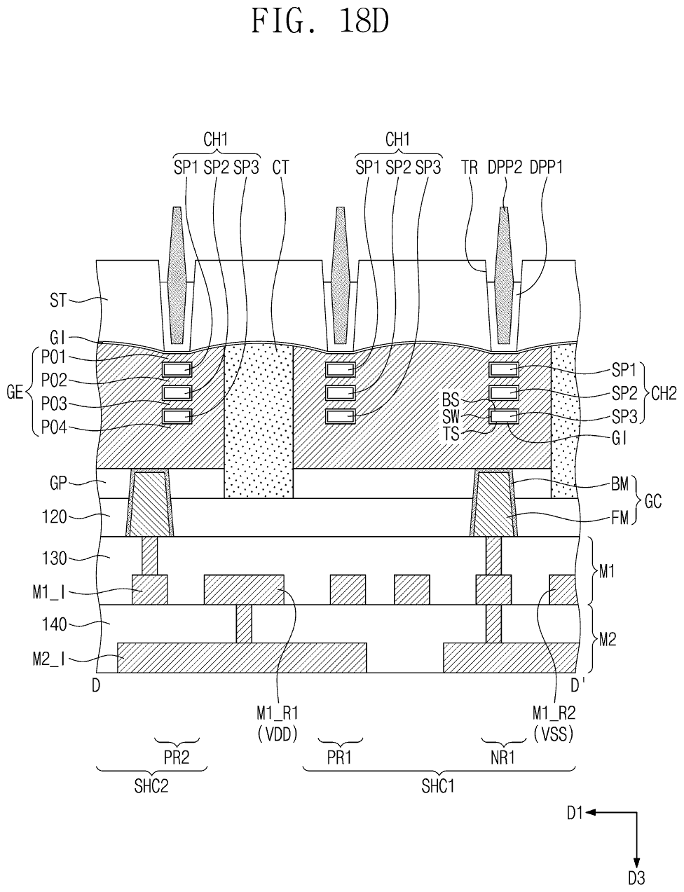

Referring to FIGS. 18A to 18D, the first filler film DPL1 may be partially removed by using etching selectivity of the first and second filler films DPL1 and DPL2. Partially removing the first filler film DPL1 may be performing an etching process on the first filler film DPL1 by using the residual mold film RSMP as a protective pattern. After the etching process is performed, the residual mold film RSMP and the second filler film DPL2 may not be removed. After the etching process is performed, the first filler pattern DPP1 may be formed. An upper surface of the first filler pattern DPP1 may be coplanar with an upper surface of the residual mold film RSMP.

After the first filler pattern DPP1 is formed, the residual mold film RSMP may be removed. Removing the residual mold film RSMP may be performing an isotropic etching process or wet etching process on the residual mold film RSMP. As another example, removing the residual mold film RSMP may be performing an ashing process. When the residual mold film RSMP is removed, the second filler film DPL2 may be partially removed. After the residual mold film RSMP is removed, the second filler pattern DPP2 may be formed. A width of the second filler pattern DPP2 in the second direction D2 may become wider and then narrower in the third direction D3.

When the residual mold film RSMP is removed, the etch stopping layer ESL, a portion of the first filler pattern DPP1, and a portion of the second filler pattern DPP2 may be exposed. A sidewall of the exposed portion of the first filler pattern DPP1 may have a negative slope, and a sidewall of the exposed portion of the second filler pattern DPP2 may have a positive slope. The first and second filler patterns DPP1 and DPP2 may constitute the rear surface filler structure DPST.

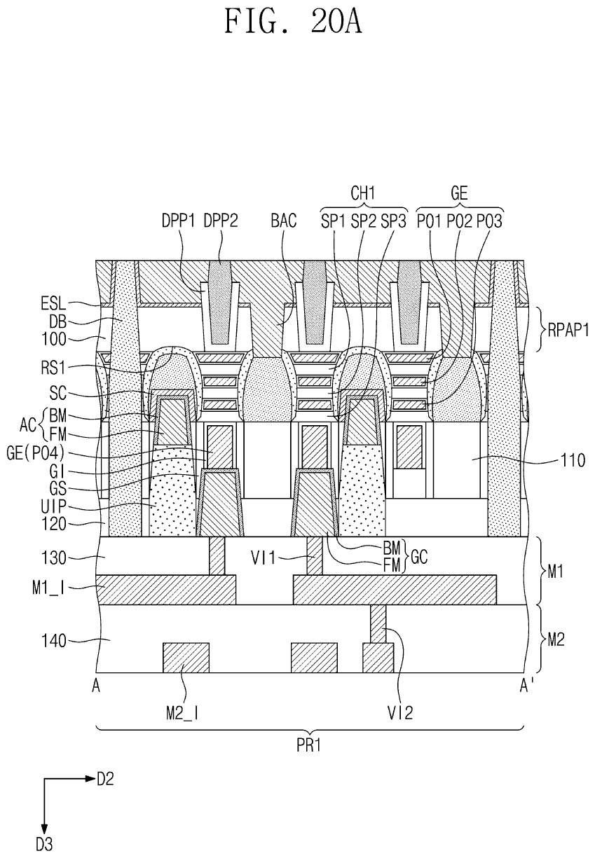

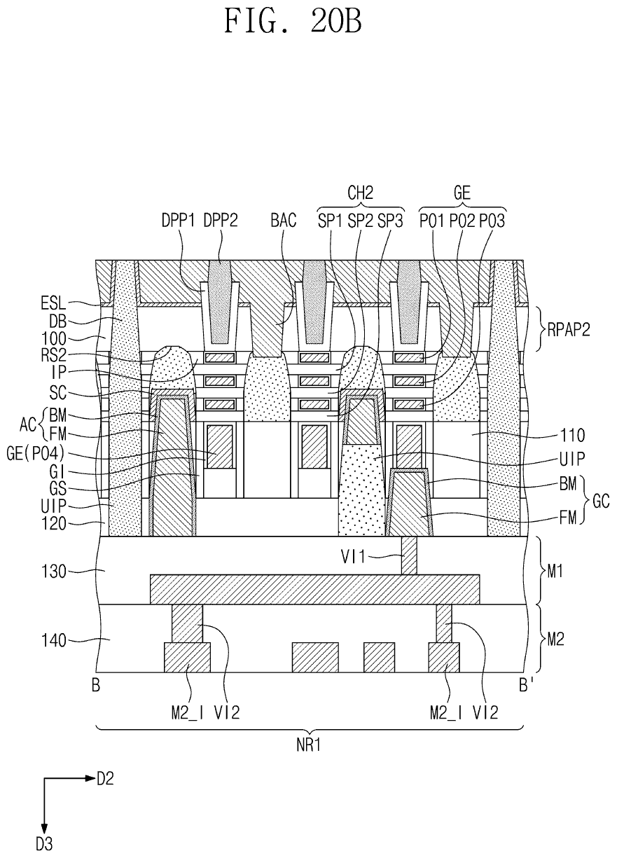

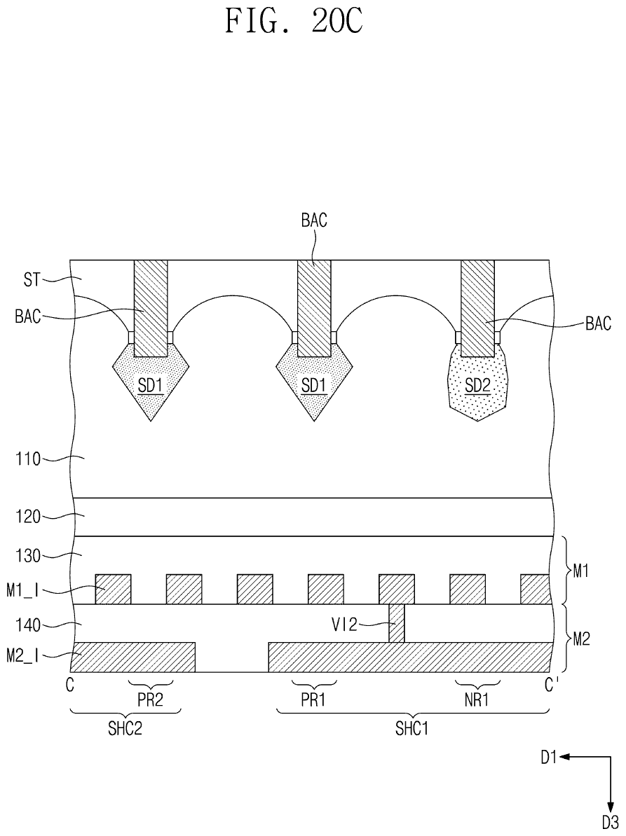

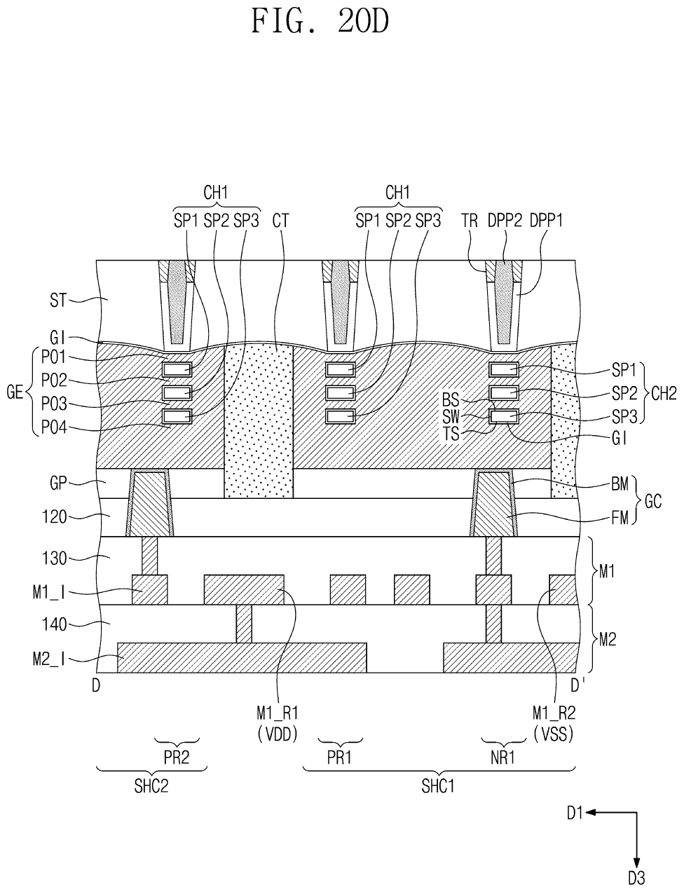

Referring to FIGS. 19 and 20A to 20D, rear surface contact holes respectively exposing the first and second source/drain patterns SD1 and SD2 may be formed. A rear surface barrier pattern and a rear surface conductive pattern may be formed on the rear surface contact holes, the substrate 100 and the etch stopping layer ESL. A rear surface active contact BAC may be formed by performing a planarization process on the rear surface conductive pattern until the upper surface of the isolation structure DB is exposed. The planarization process may be a chemical mechanical polishing (CMP) process. In other words, the rear surface barrier pattern and the rear surface conductive pattern may constitute the rear surface active contact BAC.

Since sidewalls of each of the first filler pattern DPP1 and the second filler pattern DPP2 have different slopes, the rear surface active contact BAC may be formed without a pattern defect. For example, when the rear surface barrier pattern and the rear surface conductive pattern are filled, a defect such as a void or a seam capable of occurring during deposition of a metal material may be reduced. Accordingly, reliability and electrical characteristics of the semiconductor device according to the inventive concept may be improved.

Lower power lines VPR1 to VPR3 may be formed on the rear surface active contact BAC and the rear surface filler structure DPST. The lower power lines VPR1 to VPR3 may be connected to at least one of the rear surface active contacts BAC. A power transfer network layer PDN may be formed on the lower power lines VPR1 to VPR3. The power transfer network layer PDN may be formed so as to apply a source voltage or a drain voltage to the lower power lines VPR1 to VPR3.

In a three-dimensional field effect transistor according to the inventive concept, a rear surface filler structure separating a rear surface active contact may be formed as a double layer, thereby reducing a pattern defect of the rear surface active contact. For example, since the rear surface filler structure is formed as a double layer structure, a defect such as a void or a seam capable of occurring during deposition of a metal material that constitutes the rear surface active contact may be reduced. Accordingly, reliability and electrical characteristics of a semiconductor device according to the inventive concept may be improved.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A semiconductor device comprising:
a substrate;
a lower power line disposed on a lower portion of the substrate;
a channel pattern on the substrate and including a plurality of semiconductor patterns spaced apart from each other and stacked;
a source/drain pattern connected to the channel pattern;
a gate electrode between the substrate and each of the plurality of semiconductor patterns; and
a rear surface filler structure penetrating the substrate to be disposed under the gate electrode,
wherein the rear surface filler structure includes:
a first filler pattern adjacent to the gate electrode; and
a second filler pattern disposed under the first filler pattern, and
wherein the first filler pattern covers an upper surface of the second filler pattern and a portion of each of side surfaces of the second filler pattern.

2. The semiconductor device of claim 1, wherein each of the side surfaces of the rear surface filler structure has a cascaded structure.

3. The semiconductor device of claim 1, wherein the first filler pattern and the second filler pattern comprise insulating materials that are different from each other.

4. The semiconductor device of claim 3, wherein the insulating materials comprise SiO₂, SiN, SiOC, TiO₂, or a combination thereof.

5. The semiconductor device of claim 3,
wherein the first filler pattern comprises at least one of SiO₂, SiN, SiOC, or TiO₂, and
wherein the second filler pattern comprises another one among SiO₂, SiN, SiOC, and TiO₂, different from the first filler pattern.

6. The semiconductor device of claim 1, further comprising:
a rear surface active contact penetrating the substrate to electrically connect the lower power line and the source/drain pattern,
wherein an uppermost surface of the rear surface active contact is located at a higher level than an uppermost surface of the rear surface filler structure.

7. The semiconductor device of claim 6, wherein a lowermost surface of the rear surface active contact is located at the same level as a lowermost surface of the rear surface filler structure.

8. The semiconductor device of claim 6,
wherein a lowermost surface of the rear surface active contact is located at a lower level than a lowermost surface of the first filler pattern of the rear surface filler structure, and
wherein the lowermost surface of the rear surface active contact is located at the substantially same level as a lowermost surface of the second filler pattern of the rear surface filler structure.

9. The semiconductor device of claim 6, wherein the rear surface active contact comprises a rear surface conductive pattern, and a rear surface barrier pattern surrounding the rear surface conductive pattern.

10. The semiconductor device of claim 1, wherein a lowermost surface of the first filler pattern is located at a higher level than a lowermost surface of the second filler pattern.

11. A semiconductor device comprising:
a substrate including an active pattern;
a lower power line buried in a lower portion of the substrate;
a channel pattern on the active pattern and including a plurality of semiconductor patterns, the plurality of semiconductor patterns being spaced apart from each other and stacked, and including a lowermost first semiconductor pattern;
a gate electrode crossing the active pattern, and including a first inner gate electrode interposed between the active pattern and the lowermost first semiconductor pattern;
a source/drain pattern connected to the channel pattern;
a rear surface active contact electrically connecting the lower power line and the source/drain pattern; and
a rear surface filler structure disposed under the first inner gate electrode,
wherein the rear surface filler structure includes:
a lower filler portion; and
an upper filler portion on the lower filler portion, and
wherein a slope of a sidewall of the upper filler portion is different from or the same as a slope of a sidewall of the lower filler portion.

12. The semiconductor device of claim 11,
wherein the lower filler portion comprises a first part of a second filler pattern, and
wherein the upper filler portion comprises:
a second part on the first part of the second filler pattern; and
a first filler pattern on side surfaces and an upper surface of the second part.

13. The semiconductor device of claim 11,
wherein the slope of the sidewall of the upper filler portion is a positive slope, and
wherein the slope of the sidewall of the lower filler portion is a negative slope.

14. The semiconductor device of claim 11,
wherein the slope of the sidewall of the upper filler portion is a positive slope, and
wherein the slope of the sidewall of the lower filler portion is parallel to a vertical direction of the substrate.

15. The semiconductor device of claim 11,
wherein the slope of the sidewall of the upper filler portion is a positive slope, and
wherein the slope of the sidewall of the lower filler portion is a positive slope.

16. The semiconductor device of claim 11, further comprising:
an etch stopping layer interposed between the substrate and the rear surface active contact,
wherein the etch stopping layer is in direct contact with sidewalls of a first filler pattern of the upper filler portion.

17. The semiconductor device of claim 12, further comprising:
an etch stopping layer interposed between the substrate and the rear surface active contact,
wherein the first filler pattern, the second filler pattern, and the etch stopping layer include different insulating materials.

18. A semiconductor device comprising:
a substrate including an active pattern;
an element isolation film provided on the substrate to define the active pattern;
a channel pattern on the active pattern and including a plurality of semiconductor patterns, the plurality of semiconductor patterns being spaced apart from each other and stacked, and including a first semiconductor pattern, a second semiconductor pattern, and a third semiconductor pattern;
source/drain patterns connected to the channel pattern, and including a first source/drain pattern and a second source/drain pattern horizontally spaced apart from each other;
a gate electrode between the plurality of semiconductor patterns, and including a first inner electrode, a second inner electrode, and a third inner electrode interposed between adjacent semiconductor patterns among the plurality of semiconductor patterns, and an outer electrode on the third semiconductor pattern;
a gate insulating film interposed between the gate electrode and the channel pattern;
gate spacers on sidewalls of the gate electrode;
a gate capping pattern on an upper surface of the gate electrode;
an interlayer insulating layer covering the source/drain pattern and the gate capping pattern;
an upper active contact penetrating the interlayer insulating layer to be electrically connected to the first source/drain pattern;
a metal-semiconductor compound layer interposed between the upper active contact and the first source/drain pattern;
a gate contact penetrating the interlayer insulating layer and the gate capping pattern to be electrically connected to the gate electrode;
a first metal layer on the interlayer insulating layer and including a first line electrically connected to the gate contact;
a second metal layer on the first metal layer and including a second line electrically connected to the first metal layer;
a lower power line provided under the substrate;
a rear surface active contact penetrating the substrate to electrically connect the lower power line and the second source/drain pattern; and
a rear surface filler structure penetrating the substrate to be disposed under the gate insulating film on the first inner electrode,
wherein the rear surface filler structure includes:
a first filler pattern adjacent to the gate insulating film; and
a second filler pattern provided under the first filler pattern,
wherein a bottom surface of the first filler pattern has a first level,
wherein a bottom surface of the second filler pattern has a second level, and
wherein the first level is higher than the second level.

19. The semiconductor device of claim 18,
wherein a bottom surface of the rear surface active contact has a third level, and
wherein the second level and the third level are the same level.

20. The semiconductor device of claim 18,
wherein each of side surfaces of the rear surface filler structure has a cascaded structure,
wherein the first filler pattern comprises at least one of SiO₂, SiN, SiOC, or TiO₂, and
wherein the second filler pattern comprises another one, among SiO₂, SiN, SiOC, and TiO₂, different from the first filler pattern.
